(19) United States
(12) Patent Application Publication
(10) Pub. No.: US 2025/0252988 A1
(43) Pub. Date: Aug. 7, 2025

(54) STORAGE DEVICE, ELECTRONIC APPARATUS, AND STORAGE DEVICE CONTROL METHOD

(71) Applicant: SONY SEMICONDUCTOR SOLUTIONS CORPORATION, KANAGAWA (JP)

(72) Inventors: YUTAKA HIGO, KANAGAWA (JP); LUI SAKAI, KANAGAWA (JP); KEIZO HIRAGA, KANAGAWA (JP); MASANORI HOSOMI, KANAGAWA (JP)

(21) Appl. No.: 18/856,115

(22) PCT Filed: Sep. 29, 2022
(86) PCT No.: PCT/JP2022/036596

§ 371 Date: Oct. 11, 2024

(30) Foreign Application Priority Data
Apr. 19, 2022 (JP) 2022-069010

(51) Int. Cl. G11C 11/16; H10N 50/10; H10N 50/85

(52) U.S. Cl. CPC G11C 11/1675; G11C 11/161; G11C 11/1659; G11C 11/1673; H10N 50/10; H10N 50/85

(57) ABSTRACT

A memory system (1), which is an example of a storage device according to an aspect of the present disclosure, includes: a magnetoresistive element (120) whose magnetization direction is variable between a first state and a second state by voltage application; a selection element (110) connected to the magnetoresistive element (120); and a write circuit (70) which is an example of a write unit that switchably applies, to the magnetoresistive element (120), a first write voltage for setting the magnetization direction of the magnetoresistive element (120) to the first state and a second write voltage for setting the magnetization direction of the magnetoresistive element (120) to the second state.

### FIELD

The present disclosure relates to a storage device, an electronic apparatus, and a storage device control method.

### BACKGROUND

A magnetoresistive random access memory (MRAM) using a magnetoresistive element as a storage element maintains a state by a magnetization state of a ferromagnetic material, and thus, has non-volatility in which recorded data is maintained even if a power supply is turned off. A basic structure of the magnetoresistive element is a sandwich structure in which a non-magnetic thin film of an insulator is sandwiched between two magnetic layers made of magnetic thin films. This structure is referred to as a magnetic tunnel junction (MTJ). Since a film thickness of the non-magnetic thin film is as very thin as about several nm, a tunnel current flows when a voltage is applied to both ends of the element. The magnitude of the tunnel current depends on a relative angle of magnetization of the two magnetic layers. This is called a tunnel magneto resistance (TMR) effect.

In the MRAM, magnetization of one magnetic layer (magnetization fixed layer) of the two magnetic layers is fixed, and magnetization of the other magnetic layer (storage layer) is controlled by an external field. A state where the magnetization of the magnetization fixed layer and the magnetization of the storage layer are parallel to each other is referred to as State 0, and a state where the magnetization of the magnetization fixed layer and the magnetization of the storage layer are antiparallel to each other is referred to as State 1. In this manner, the state (“0” or “1”) is stored in a non-volatile manner by rewriting the parallel or antiparallel state of magnetization. As for the external field used to control a magnetization direction, a current magnetic field generated by causing a current to flow to an external wiring, a method of utilizing a spin transfer torque (STT) effect by causing a current to flow directly to the MTJ, a method of utilizing voltage controlled magnetic anisotropy (VCMA), and the like are used. The TMR effect is used to read the state.

A currently mainstream MRAM is an STT-MRAM that can be reduced in size as compared with a case of using a current magnetic field and can reduce power consumption. On the other hand, attention has been paid to a voltage controlled (VC) MRAM utilizing VCMA since writing can be performed at a high speed and with lower power consumption. A voltage write scheme utilizing VCMA disclosed in Patent Literature 1 implements bidirectional writing by applying an ultrafast pulse voltage in a unipolar manner (applying the voltage only in one direction).

In the conventional voltage write scheme, a bidirectional write operation is performed with a unipolar voltage. When no voltage is applied to an MTJ, magnetization is oriented in a direction (z direction) perpendicular to a film surface due to perpendicular magnetic anisotropy (a property that magnetization is likely to be oriented in the direction perpendicular to the film surface) of a storage layer. Similarly, magnetization of a fixed layer is oriented in the z direction due to the perpendicular magnetic anisotropy. Here, it is assumed that both the magnetization of the storage layer and the magnetization of the fixed layer are in a +z direction, that is, in a parallel state, and State 0 is written. Further, it is assumed that an external magnetic field is applied in a +x direction among in-plane directions (an x direction and a y direction). Here, when a voltage is applied to the MTJ, the perpendicular magnetic anisotropy of the storage layer disappears due to an electric field generated in the vicinity of an interface between a non-magnetic layer and the storage layer, and the property that the magnetization is likely to be oriented in the direction perpendicular to the film surface is lost. As a result, the magnetization of the storage layer starts to move toward the x direction in which magnetic energy is minimized due to the external magnetic field, and starts so-called precessional motion that gradually moves toward the +x direction while circling in a yz plane instead of a simple change in a straight line from the +z direction to the +x direction. There is a moment when the magnetization of the storage layer initially oriented in the +z direction is oriented substantially in a −z direction in the process of the precessional motion in the yz plane. When the voltage applied to the MTJ at this time is set to zero, the perpendicular magnetic anisotropy of the storage layer returns to the original state, and the magnetization is likely to be oriented in the direction perpendicular to the film surface, so that the magnetization of the storage layer is fixed in the −z direction. That is, State 1 in which the magnetization of the storage layer and the magnetization of the fixed layer become antiparallel from State 0 is written by applying a pulsed voltage. A similar phenomenon occurs even when the magnetization of the storage layer is initially oriented in the −z direction, the bidirectional writing can be implemented by applying a unipolar pulse voltage.

### CITATION LIST

### Patent Literature

Patent Literature 1: JP 2018-092696 A

### SUMMARY

### Technical Problem

However, the above-described write scheme is a so-called toggle write scheme in which a change from State 0 to State 1 and a change from State 1 to State 0 can be made by applying a pulse voltage of the same magnitude to an MTJ. For this reason, for example, when State 1 is to be written already in State 1, State 0 is erroneously written. In order to prevent such erroneous writing, it is necessary to read an initial state before writing. For example, when State 1 is to be written, the already written initial state is read. Then, if the initial state is State 0, writing is performed to set State 1. On the other hand, if the initial state is State 1, writing is not performed. The erroneous writing can be prevented by performing initial reading in this manner. Meanwhile, read time generally requires 10 ns or longer, and power is consumed at the time of reading. This impairs the high-speed and low-power consumption characteristics of the VC-MRAM.

Therefore, the present disclosure provides a storage device, an electronic apparatus, and a storage device control method which enable high-speed and low-power consumption writing.

### Solution to Problem

A storage device according to the embodiment of the present disclosure includes: a magnetoresistive element whose magnetization direction is variable between a first state and a second state by voltage application; a selection element connected to the magnetoresistive element; and a write unit that switchably applies, to the magnetoresistive element, a first write voltage for setting the magnetization direction of the magnetoresistive element to the first state and a second write voltage for setting the magnetization direction of the magnetoresistive element to the second state.

An electronic apparatus according to the embodiment of the present disclosure includes a storage device that stores data, the storage device including: a magnetoresistive element whose magnetization direction is variable between a first state and a second state by voltage application; a selection element connected to the magnetoresistive element; and a write unit that switchably applies, to the magnetoresistive element, a first write voltage for setting the magnetization direction of the magnetoresistive element to the first state and a second write voltage for setting the magnetization direction of the magnetoresistive element to the second state.

A storage device control method according to the embodiment of the present disclosure includes switchably applying, to a magnetoresistive element whose magnetization direction is variable between a first state and a second state by voltage application, a first write voltage for setting the magnetization direction of the magnetoresistive element to the first state and a second write voltage for setting the magnetization direction of the magnetoresistive element to the second state.

### BRIEF DESCRIPTION OF DRAWINGS

FIG. 1 is a diagram illustrating a first configuration example of a memory system according to an embodiment of the present disclosure.

FIG. 2 is a diagram illustrating a second configuration example of the memory system according to the embodiment of the present disclosure.

FIG. 3 is a diagram illustrating a first configuration example of a memory cell according to the embodiment of the present disclosure.

FIG. 4 is a diagram illustrating a second configuration example of the memory cell according to the embodiment of the present disclosure.

FIG. 5 is a diagram illustrating a first configuration example of a magnetoresistive element according to the embodiment of the present disclosure.

FIG. 6 is a diagram illustrating a second configuration example of the magnetoresistive element according to the embodiment of the present disclosure.

FIG. 7 is a diagram schematically illustrating the memory cell according to the embodiment of the present disclosure.

FIG. 8 is a view illustrating a first relationship between a voltage and a current applied to the memory cell according to the embodiment of the present disclosure.

FIG. 9 is a view illustrating a second relationship between the voltage and the current applied to the memory cell according to the embodiment of the present disclosure.

FIG. 10 is a view for describing a bit line voltage in a first example of simulation results according to the embodiment of the present disclosure.

FIG. 11 is a view for describing a word line voltage in the first example of the simulation results according to the embodiment of the present disclosure.

FIG. 12 is a view for describing the first example of the simulation results according to the embodiment of the present disclosure.

FIG. 13 is a view for describing a bit line voltage in a second example of the simulation results according to the embodiment of the present disclosure.

FIG. 14 is a view for describing a word line voltage in the second example of the simulation results according to the embodiment of the present disclosure.

FIG. 15 is a view for describing the second example of the simulation results according to the embodiment of the present disclosure.

FIG. 16 is a view illustrating a first example of a processing procedure of write processing according to the embodiment of the present disclosure.

FIG. 17 is a view illustrating a second example of the processing procedure of the write processing according to the embodiment of the present disclosure.

FIG. 18 is a view illustrating a third example of the processing procedure of the write processing according to the embodiment of the present disclosure.

FIG. 19 is a view illustrating a fourth example of the processing procedure of the write processing according to the embodiment of the present disclosure.

FIG. 20 is a view for describing a first example of a continuous write method according to the embodiment of the present disclosure.

FIG. 21 is a view for describing a second example of the continuous write method according to the embodiment of the present disclosure.

FIG. 22 is a view for describing a third example of the simulation results according to the embodiment of the present disclosure.

FIG. 23 is a view for describing a fourth example of the simulation results according to the embodiment of the present disclosure.

FIG. 24 is a view for describing a first example of a write method of the magnetoresistive element according to the embodiment of the present disclosure.

FIG. 25 is a view for describing a fifth example of the simulation results according to the embodiment of the present disclosure.

FIG. 26 is a view for describing a sixth example of the simulation results according to the embodiment of the present disclosure.

FIG. 27 is a view for describing a seventh example of the simulation results according to the embodiment of the present disclosure.

FIG. 28 is a view for describing an eighth example of the simulation results according to the embodiment of the present disclosure.

FIG. 29 is a view illustrating a first example of a write pulse shape according to the embodiment of the present disclosure.

FIG. 30 is a view illustrating a second example of the write pulse shape according to the embodiment of the present disclosure.

FIG. 31 is a view illustrating a third example of the write pulse shape according to the embodiment of the present disclosure.

FIG. 32 is a view illustrating a fourth example of the write pulse shape according to the embodiment of the present disclosure.

FIG. 33 is a view illustrating a fifth example of the write pulse shape according to the embodiment of the present disclosure.

FIG. 34 is a diagram illustrating a first configuration example of a write pulse generation circuit according to the embodiment of the present disclosure.

FIG. 35 is a view for describing an operation example of the write pulse generation circuit in the first configuration example according to the embodiment of the present disclosure.

FIG. 36 is a view for describing an operation example of the write pulse generation circuit in the first configuration example according to the embodiment of the present disclosure.

FIG. 37 is a diagram illustrating a second configuration example of the write pulse generation circuit according to the embodiment of the present disclosure.

FIG. 38 is a view for describing a second example of the write method of the magnetoresistive element according to the embodiment of the present disclosure.

FIG. 39 is a view illustrating a sixth example of the write pulse shape according to the embodiment of the present disclosure.

FIG. 40 is a view for describing a ninth example of the simulation results according to the embodiment of the present disclosure.

FIG. 41 is a view for describing a tenth example of the simulation results according to the embodiment of the present disclosure.

FIG. 42 is a view for describing a first example of a constraint of the write pulse shape according to the embodiment of the present disclosure.

FIG. 43 is a view illustrating a seventh example of the write pulse shape according to the embodiment of the present disclosure.

FIG. 44 is a view for describing a third example of the write method of the magnetoresistive element according to the embodiment of the present disclosure.

FIG. 45 is a view for describing an eleventh example of the simulation results according to the embodiment of the present disclosure.

FIG. 46 is a view for describing a twelfth example of the simulation results according to the embodiment of the present disclosure.

FIG. 47 is a view for describing a second example of the constraint of the write pulse shape according to the embodiment of the present disclosure.

FIG. 48 is a view for describing a third example of the constraint of the write pulse shape according to the embodiment of the present disclosure.

FIG. 49 is a view illustrating an eighth example of the write pulse shape according to the embodiment of the present disclosure.

FIG. 50 is a view for describing a fourth example of the constraint of the write pulse shape according to the embodiment of the present disclosure.

FIG. 51 is a view for describing a fifth example of the constraint of the write pulse shape according to the embodiment of the present disclosure.

FIG. 52 is a view for describing a sixth example of the constraint of the write pulse shape according to the embodiment of the present disclosure.

FIG. 53 is a view illustrating a ninth example of the write pulse shape according to the embodiment of the present disclosure.

FIG. 54 is a view for describing a seventh example of the constraint of the write pulse shape according to the embodiment of the present disclosure.

FIG. 55 is a view for describing an eighth example of the constraint of the write pulse shape according to the embodiment of the present disclosure.

FIG. 56 is a view for describing a ninth example of the constraint of the write pulse shape according to the embodiment of the present disclosure.

FIG. 57 is a view for describing a tenth example of the constraint of the write pulse shape according to the embodiment of the present disclosure.

FIG. 58 is a view illustrating a fifth example of the processing procedure of the write processing according to the embodiment of the present disclosure.

FIG. 59 is a view for describing a first example of a write method using initial writing according to the embodiment of the present disclosure.

FIG. 60 is a view for describing a second example of the write method using initial writing according to the embodiment of the present disclosure.

FIG. 61 is a view for describing a thirteenth example of the simulation results according to the embodiment of the present disclosure.

FIG. 62 is a view for describing a fourteenth example of the simulation results according to the embodiment of the present disclosure.

FIG. 63 is a diagram illustrating an example of a schematic configuration of an imaging device.

FIG. 64 is a diagram illustrating an example of a schematic configuration of a distance measurement device.

FIG. 65 is a view illustrating an example of an appearance of a game apparatus.

FIG. 66 is a diagram illustrating an example of a schematic configuration of the game apparatus.

### DESCRIPTION OF EMBODIMENTS

Hereinafter, embodiments of the present disclosure will be described in detail with reference to the drawings. Note that devices, apparatuses, methods, and the like according to the present disclosure are not limited by the embodiments, and various numerical values, materials, and the like according to the embodiments are examples. Further, the same portions are basically denoted by the same reference signs in the following embodiments, and a repetitive description thereof will be omitted.

One or a plurality of embodiments (including examples and modifications) to be described hereinafter can be implemented independently. Meanwhile, at least some of the plurality of embodiments to be described hereinafter may be implemented appropriately in combination with at least some of other embodiments. The plurality of embodiments may include novel features different from each other. Therefore, the plurality of embodiments can contribute to achieving mutually different objects or solutions to problems, and can exhibit mutually different effects. Note that the effects of the respective embodiments are merely examples and are not limited, and additional effects may be present.

Further, the drawings referred to in the following description are drawings for facilitating the description and understanding of an embodiment of the present disclosure, and shapes, dimensions, ratios, and the like illustrated in the drawings are sometimes different from actual ones for the sake of clarity. Furthermore, an element and the like illustrated in the drawings can be appropriately modified in design in consideration of the following description and known techniques. Further, in the following description, a vertical direction of a laminate structure of the element and the like corresponds to a relative direction in a case where a surface of a substrate on which the element is provided is facing upward, and is sometimes different from the vertical direction according to actual gravitational acceleration.

Note that terms such as “perpendicular direction” (a direction perpendicular to a film surface or a laminating direction of the laminate structure) and “in-plane direction” (a direction parallel to the film surface or a direction perpendicular to the laminating direction of the laminate structure) are sometimes used for convenience when the description regarding a magnetization direction (magnetic moment) or magnetic anisotropy is given. However, these terms do not necessarily mean the exact directions of magnetization. For example, an expression such as “the magnetization direction is the perpendicular direction” or “having perpendicular magnetic anisotropy” means a state where magnetization in the perpendicular direction is superior to magnetization in the in-plane direction. Similarly, for example, an expression such as “the magnetization direction is the in-plane direction” or “having in-plane magnetic anisotropy” means a state where magnetization in the in-plane direction is superior to magnetization in the perpendicular direction.

Here, the present inventors have developed a compact model, described in Verilog-A language, of an MTJ having the VCMA effect that can be incorporated into a simulation program with integrated circuit emphasis (SPICE) simulator and invented a non-toggle write scheme as a result of research by a SPICE simulation using this MTJ model. In the non-toggle write scheme of the present disclosure, for example, in a memory cell in which a cell transistor and the MTJ are connected in series, voltages of different magnitudes are applied to the memory cell between the case of writing State 1 and the case of writing State 0. In this case, the voltage applied to the memory cell is divided by the cell transistor and the MTJ, and the voltage divided and applied to the MTJ changes depending on a state already written in the MTJ. As a result, it is possible to prevent erroneous writing from occurring when State 1 is to be written in a state where State 1 has been written and when State 0 is to be written in a state where State 0 has been written. Therefore, it is unnecessary to read an initial state before writing in the non-toggle write scheme of the present disclosure, whereas it is necessary to read the initial state before writing in a toggle write scheme of the related art. Therefore, it is possible to reduce read time and power consumption required at the time of initial reading. The non-toggle write scheme of the present disclosure will be described later in detail.

The present disclosure will be described in the following item order.
1. Embodiment
1-1. Configuration Example of Memory System
1-2. Configuration Example of Memory Cell
1-3. Configuration Example of Magnetoresistive Element
1-4. Write Scheme Using Rectangular Pulse
1-5. Simulation Result
1-6. Write Processing
1-7. Write Scheme Using Non-Rectangular Pulse
1-8. Write Pulse Generation Circuit
1-9. Write Scheme Using Rectangular Long Pulse
1-10. Write Scheme Using Gradient Long Pulse
1-11. Write Scheme Using Sawtooth Pulse
1-12. Write Scheme Using Initial Writing
1-13. Action and Effect
2. Other Embodiments
3. Configuration Example of Electronic Apparatus
3-1. Imaging Device
3-2. Distance Measurement Device
3-3. Game Apparatus
4. Appendix

### 1. Embodiment

### 1-1. Configuration Example of Memory System

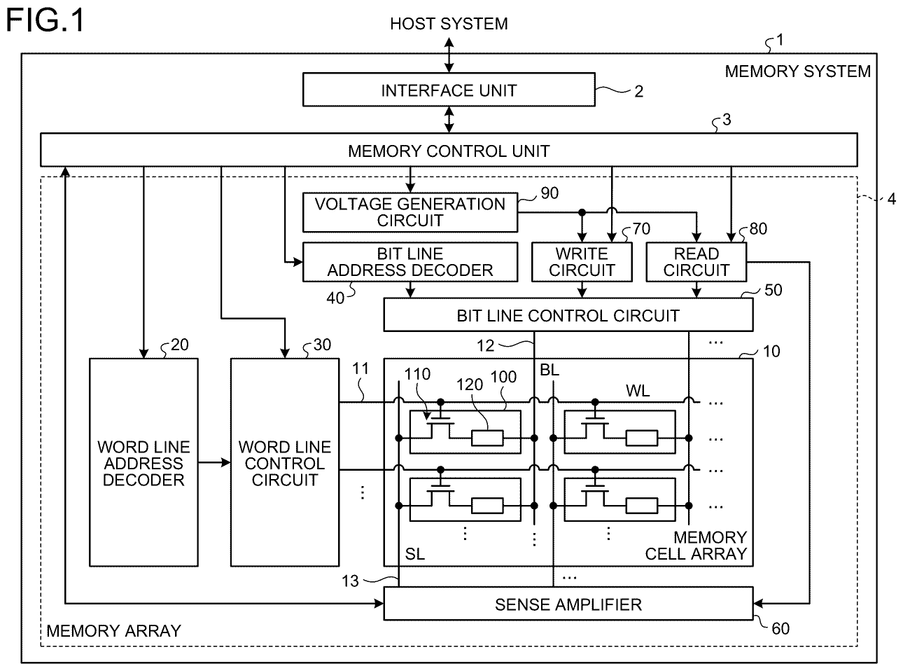

A configuration example of a memory system 1 according to the present embodiment will be described with reference to FIG. 1. FIG. 1 is a diagram illustrating the configuration example of the memory system 1 according to the present embodiment. The memory system 1 is an example of a storage device that holds information using a magnetization direction of a magnetic material.

As illustrated in FIG. 1, the memory system 1

according to the present embodiment includes an interface unit 2, a memory control unit 3, and a memory array 4.

The interface unit 2 exchanges (for example, performs transmission and reception of) signals with a host system or the like using the memory system 1.

The memory control unit 3 exchanges data with the host system or the like to control the memory array 4. The memory control unit 3 receives a command from the host system or the like, and controls writing and reading of data on the basis of the received command. For example, the memory control unit 3 outputs commands and addresses for writing and reading, and data to be written to the memory array 4. Further, the memory control unit 3 outputs the command for reading, and then receives read data from the memory array 4.

The memory array 4 stores data. The memory array 4 includes a memory cell array 10, a word line address decoder 20, a word line control circuit 30, a bit line address decoder 40, a bit line control circuit 50, a sense amplifier 60, a write circuit 70, a read circuit 80, and a voltage generation circuit 90. The write circuit 70 functions as a write unit.

The memory cell array 10 is configured by arranging memory cells 100 each storing data in a two-dimensional matrix. The memory cell 100 includes a selection element 110 and a magnetoresistive element 120. As the magnetoresistive element 120, for example, a magnetoresistive element such as an MTJ can be used. The selection element 110 is an element that is connected to one end of the magnetoresistive element 120 and controls application of a voltage to the magnetoresistive element 120. As the selection element 110, for example, an n-channel MOS transistor can be used.

A word line 11 (WL) and a bit line 12 (BL), which transmit a control signal, are connected to the memory cell 100. In the memory cell 100, a source line 13 (SL) transmitting a signal from the magnetoresistive element 120 is further arranged. In the memory cell array 10, a plurality of the word lines 11 are wired so as to extend in the row direction, and a plurality of the bit lines 12 and a plurality of the source lines 13 are wired so as to extend in the column direction.

The word line address decoder 20 selects the word line 11 of the memory cell array 10 on the basis of the control signal from the memory control unit 3.

The word line control circuit 30 outputs the control signal to the word line 11 selected by the word line address decoder 20.

The bit line address decoder 40 selects the bit line 12 of the memory cell array 10 on the basis of the control signal from the memory control unit 3.

The bit line control circuit 50 outputs the control signal to the bit line 12 selected by the bit line address decoder 40.

The sense amplifier 60 reads data by detecting a current flowing through the memory cell 100 at the time of reading. The read data is output to the memory control unit 3.

The write circuit 70 is a circuit that performs writing with respect to the memory cell 100 at an intersection of the selected word line 11 and the selected bit line 12. The write circuit 70 performs writing on the magnetoresistive element 120 via the selection element 110 of the memory cell 100.

The read circuit 80 is a circuit that performs reading with respect to the memory cell 100 at an intersection of the selected word line 11 and the selected bit line 12. The read circuit 80 performs reading on the magnetoresistive element 120 via the selection element 110 of the memory cell 100.

The voltage generation circuit 90 is a circuit that generates a voltage to be applied at the time of writing and reading of the memory cell 100.

Here, reading can be performed by applying a predetermined read voltage to the magnetoresistive element 120 of the memory cell 100 and detecting a current flowing through the memory cell 100 although details of writing with respect to the memory cell 100 will be described later. Note that the read voltage is preferably a voltage having a polarity different from that of a write voltage.

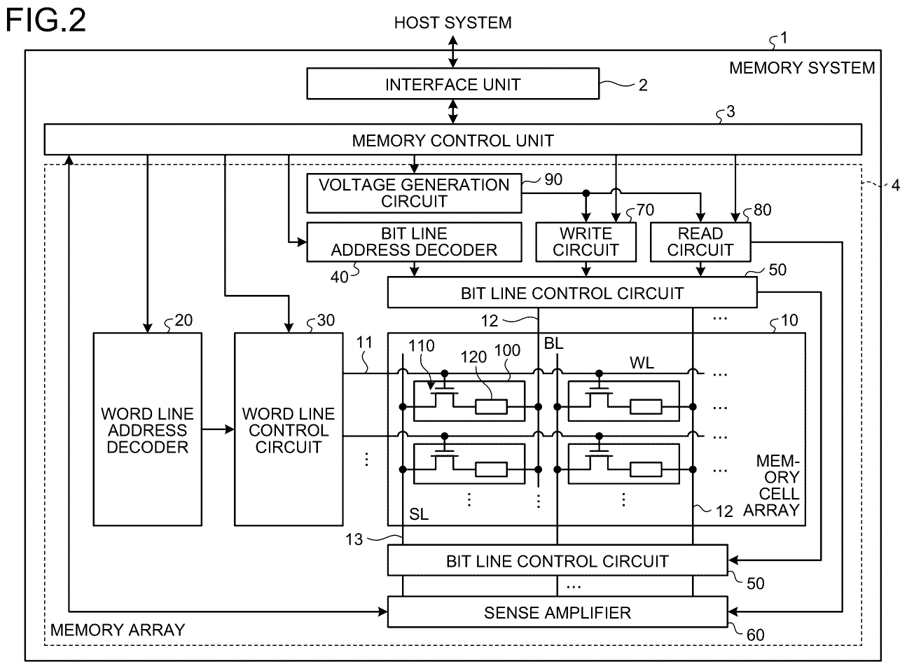

Next, another configuration example of the memory system 1 according to the present embodiment will be described with reference to FIG. 2. FIG. 2 is a diagram illustrating another configuration example of the memory system 1 according to the embodiment of the present disclosure. The memory system 1 is also an example of the storage device that holds information using the magnetization direction of the magnetic material.

As illustrated in FIG. 2, two bit line control circuits 50 are arranged above and below the memory cell array 10, which is different from FIG. 1. As a result, for example, the bit line control circuit 50 arranged on the upper side can control the even-numbered bit lines 12, and the bit line control circuit 50 arranged on the lower side can control the odd-numbered bit lines 12. The other functions are similar to those of the memory system 1 illustrated in FIG. 1.

### 1-2. Configuration Example of Memory Cell

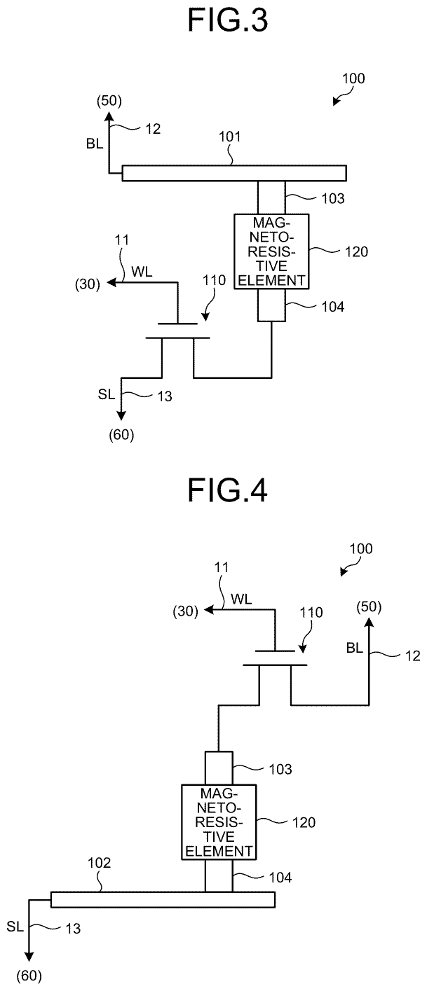

Configuration examples of the memory cell 100 according to the present embodiment will be described with reference to FIGS. 3 and 4. FIGS. 3 and 4 are diagrams each illustrating the configuration example of the memory cell 100 according to the present embodiment. Each drawing is a schematic diagram illustrating the configuration example of the memory cell 100. Note that the memory cell 100 includes the selection element 110 and the magnetoresistive element 120 as described above. In the examples of FIGS. 3 and 4, the selection element 110 and the magnetoresistive element 120 are connected in series, and the selection element 110 has a drain (drain terminal), a source (source terminal), and a gate (gate terminal).

As illustrated in FIG. 3, the magnetoresistive element 120 of the memory cell 100 is connected to a wiring 101 via a contact layer 103, and is connected to the selection element 110 via a contact layer 104. The selection element 110 has the drain connected to the contact layer 104, and the source connected to the source line 13 (SL). Further, the gate of the selection element 110 is connected to the word line 11 (WL). Note that the contact layer 103 is connected to the wiring 101 constituting the bit line 12 (BL). When an on-voltage is applied to the word line 11 (WL), the selection element 110 is energized, and a voltage can be applied to the magnetoresistive element 120.

As illustrated in FIG. 4, the magnetoresistive element 120 of the memory cell 100 is connected to a wiring 102 via the contact layer 104, and is connected to the selection element 110 via the contact layer 103. The selection element 110 has the drain connected to the bit line 12 (BL) and the source connected to the contact layer 103. Further, the gate of the selection element 110 is connected to the word line 11 (WL). Note that the contact layer 104 is connected to the wiring 102 constituting the source line 13 (SL). When an on-voltage is applied to the word line 11 (WL), the selection element 110 is energized, and a voltage can be applied to the magnetoresistive element 120.

As described above, the word line 11 (WL) is connected to the word line control circuit 30 (see FIGS. 1 and 2). The bit line 12 (BL) is connected to the bit line control circuit 50 (see FIGS. 1 and 2). The source line 13 (SL) is connected to the sense amplifier 60 (see FIGS. 1 and 2). A voltage for writing or reading can be applied to the magnetoresistive element 120 by applying a voltage between the bit line 12 (BL) and the source line 13 (SL) and applying the on-voltage for energizing the selection element 110 to the word line 11 (WL).

### 1-3. Configuration Example of Magnetoresistive Element

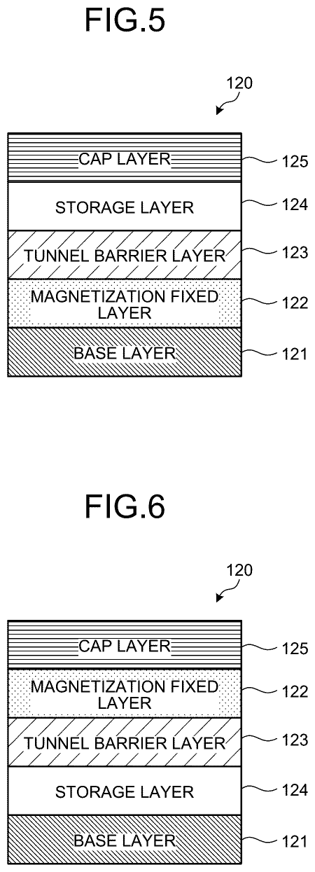

Configuration examples of the magnetoresistive element 120 according to the present embodiment will be described with reference to FIGS. 5 and 6. FIGS. 5 and 6 are views each illustrating the configuration example of the magnetoresistive element 120 according to the present embodiment. Each drawing is a cross-sectional view illustrating the configuration example of the magnetoresistive element 120.

As illustrated in FIGS. 5 and 6, the magnetoresistive element 120 includes a base layer 121, a magnetization fixed layer 122, a tunnel barrier layer 123, a storage layer 124, and a cap layer 125. The magnetoresistive element 120 illustrated in FIG. 5 is configured by sequentially laminating the base layer 121, the magnetization fixed layer 122, the tunnel barrier layer 123, the storage layer 124, and the cap layer 125. On the other hand, the magnetoresistive element 120 illustrated in FIG. 6 is configured by sequentially laminating the base layer 121, the storage layer 124, the tunnel barrier layer 123, the magnetization fixed layer 122, and the cap layer 125.

As the base layer 121, for example, a layer formed of a noble metal such as Cr, Ta, Ru, Au, Ag, Cu, Al, Ti, V, Mo, Zr, Hf, Re, W, Pt, Pd, Ir, or Rh or a transition metal element, and a laminate structure thereof can be used. Further, the base layer 121 can also be made of a conductive nitride such as TiN. For example, the base layer 121 is configured using a film for controlling a crystal orientation of the magnetization fixed layer 122 and improving an adhesion strength to a lower electrode.

The magnetization fixed layer 122 is a layer having magnetic anisotropy and an invariable magnetization direction. The magnetization fixed layer 122 can be made of, for example, CoFeB, a CoFeC alloy, a NiFeB alloy, a NiFeC alloy, or the like. Further, the magnetization fixed layer 122 can have a laminated ferri-pin structure in which a plurality of ferromagnetic layers are laminated with a non-magnetic layer interposed therebetween. As a material of the ferromagnetic layer constituting the magnetization fixed layer having the laminated ferri-pin structure, Co, CoFe, CoFeB, or the like can be used. Further, as a material of the non-magnetic layer, Ru, Re, Ir, Os, or the like can be used.

Further, the magnetization fixed layer 122 can be configured such that the orientation of magnetization is fixed by utilizing antiferromagnetic coupling between an antiferromagnetic layer and a ferromagnetic layer. Examples of a material of the antiferromagnetic layer can include magnetic materials such as a FeMn alloy, a PtMn alloy, a PtCrMn alloy, a NiMn alloy, an IrMn alloy, a NiO, and a Fe2O3. Further, a non-magnetic element such as Ag, Cu, Au, Al, Si, Bi, Ta, B, C, O, N, Pd, Pt, Zr, Hf, Ir, W, Mo, or Nb can be added to these magnetic materials.

The tunnel barrier layer 123 is arranged adjacent to the storage layer 124 to be described later, and applies an electric field to the storage layer 124 to impart the voltage-controlled magnetic anisotropy effect. The tunnel barrier layer 123 can be made of an oxide of at least one element selected from the group of Mg, Al, Ti, Si, Zn, Zr, Hf, Ta, Bi, Cr, Ga, La, Gd, Sr, and Ba, or a nitride of at least one element selected from the group of Mg, Al, Ti, Si, Zn, Zr, Hf, Ta, Bi, Cr, Ga, La, Gd, Sr, and Ba. Further, it can also be configured using an insulator such as MgF2, CaF, SrTiO2, AlLaO3, or AlNO, a dielectric, and a semiconductor. It is also possible to have a structure in which these layers are laminated. Note that a thickness of the tunnel barrier layer 123 is preferably 0.6 nm or more.

The storage layer 124 is a layer having magnetic anisotropy and a variable magnetization direction. Further, the storage layer 124 is a layer having the VCMA effect. A state where the magnetization direction of the storage layer 124 and the magnetization direction of the magnetization fixed layer 122 are identical and a state where the magnetization direction of the storage layer 124 and the magnetization direction of the magnetization fixed layer 122 are different are referred to as a parallel state and an antiparallel state, respectively. The magnetoresistive element 120 is in a low resistance state in the parallel state, and is in a high resistance state in the antiparallel state. The magnetization direction of the storage layer 124 can be changed by applying a voltage to the magnetoresistive element 120 as described above.

Further, the storage layer 124 can be made of cobalt iron (CoFe), cobalt iron boron (CoFeB), Fe, iron boride (FeB), or the like. Further, it is also possible to adopt a configuration including a transition metal (Hf, Ta, W, Re, Ir, Pt, Au, Zr, Nb, Mo, Ru, Rh, Pd, Ag, Ti, V, Cr, Mn, Ni, or Cu) or the like. Further, a nitride or an oxide may be included. Further, iridium (Ir) or osmium (Os) can be used as a material that induces a proximity magnetic moment to the magnetic material. Note that a heavy metal can also be added to the storage layer 124 to improve the voltage-controlled magnetic anisotropy effect. A thickness of the storage layer 124 is preferably 3.0 nm or less.

Further, the storage layer 124 may have a laminate structure in which a plurality of ferromagnetic layers are laminated with a non-magnetic layer interposed therebetween. At this time, two ferromagnetic layers adjacent to each other with the non-magnetic layer interposed therebetween may be exchange-coupled. The non-magnetic layer can be made of Mg, Al, Ti, Si, Zn, Zr, Hf, Ta, Bi, Cr, Ga, La, Gd, Sr, Ba, W, Re, Ir, Pt, Au, Nb, Mo, Ru, Rh, Pd, Ag, V, Mn, Ni, Cu, or the like.

The cap layer 125 is a layer that prevents diffusion of a metal from a wiring member. The cap layer 125 can be made of a metal such as Cr, Ta, Ru, Au, Ag, Cu, Al, Ti, V, Mo, Zr, Hf, Re, W, Pt, Pd, Ir, or Rh. Further, the cap layer 125 can be configured using a layer formed of an alloy containing them or a transition metal element. Further, the cap layer 125 can also be configured by laminating them. Further, the cap layer 125 can also be made of a conductive nitride such as TiN.

The above-described various layers can be produced by, for example, a physical vapor deposition (PVD) method typified by a sputtering method, an ion beam deposition method, and a vacuum vapor deposition method, and a chemical vapor deposition (CVD) method typified by an atomic layer deposition (ALD) method. Further, patterning of these layers can be performed by a reactive ion etching (RIE) method or an ion milling method. It is preferable to form the various layers consecutively in a vacuum apparatus, and it is preferable to perform patterning thereafter.

### 1-4. Write Scheme Using Rectangular Pulse

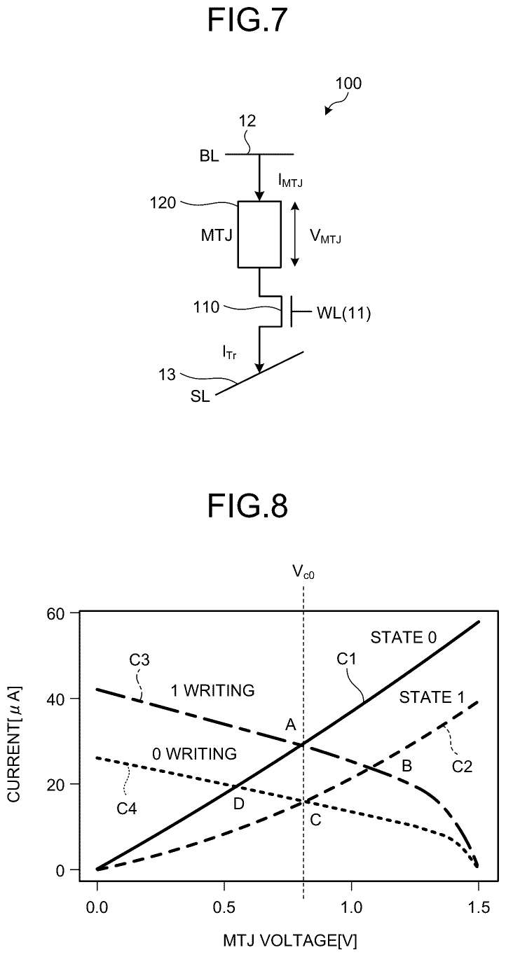

A write scheme using a rectangular pulse according to the present embodiment will be described with reference to FIGS. 7 to 9.

FIG. 7 is a diagram schematically illustrating the memory cell 100. In an example of FIG. 7, the magnetoresistive element 120 is an MTJ (MTJ element), and the selection element 110 is an n-channel MOS transistor. As described above, it is possible to cause a current to flow through the memory cell 100 by applying voltages to the bit line 12 (BL), the source line 13 (SL), and the word line 11 (WL) connected to the memory cell 100.

Here, a bit line voltage of the bit line 12 (BL) is denoted by V_{BL}, a source line voltage of the source line 13 (SL) is denoted by V_{SL}, and a word line voltage of the word line 11 (WL) is denoted by V_{WL}. Further, an MTJ voltage applied to the MTJ is defined by V_{MTJ}. It is necessary to set the magnetic anisotropy of the storage layer 124 to zero by applying a voltage (write voltage) to the MTJ in order to perform writing using the VCMA effect. The MTJ voltage V_{MTJ} when the magnetic anisotropy of the storage layer 124 becomes zero is denoted by V_{c0}. Since the MTJ voltage V_{MTJ} depends on the bit line voltage V_{BL}, the source line voltage V_{SL}, and the word line voltage V_{WL}, it is necessary to adjust these voltages such that the MTJ voltage V_{MTJ} becomes V_{c0}.

FIG. 8 is a view plotting a relationship between the MTJ voltage V_{MTJ} and a current flowing through the memory cell 100. Here, a curve C1 represents an MTJ current in State 0, and a curve C2 represents an MTJ current in State 1. Since a resistance value in State 0 is smaller than a resistance value in State 1, the MTJ current in State 0 is larger than the MTJ current in State 1 at the same MTJ voltage. Further, a curve C3 represents a transistor current in writing of State 1, and a curve C4 represents a transistor current in writing of State 0. Here, the source line voltage V_{SL} is grounded, the word line voltage V_{WL} has different values between the writing of State 0 and the writing of State 1 and the bit line voltage V_{BL} has the same value between the writing of State 0 and the writing of State 1.

As can be seen from FIG. 7, the voltage V_{MTJ} applied to the MTJ by applying a voltage to the memory cell 100 becomes intersections of the curves C1 to C4 since the MTJ current and the transistor current have the same value. Specifically, in a case where State 1 is to be written in State 0, a voltage indicated by an intersection A of the curve C1 and the curve C3 is applied to the MTJ. In a case where State 1 is to be written in State 1, a voltage indicated by an intersection B of the curve C2 and the curve C3 is applied to the MTJ. In a case where State 0 is to be written in State 1, a voltage indicated by an intersection C of the curve C2 and the curve C4 is applied to the MTJ. In a case where State 0 is to be written in State 0, a voltage indicated by an intersection D of the curve C1 and the curve C4 is applied to the MTJ. It is noted that the voltages at the intersections A and C match the voltage V_{c0} at which the magnetic anisotropy of the storage layer 124 becomes zero. Conversely, the word line voltage V_{WL} is adjusted such that the voltages at the intersections A and C match the voltage V_{c0}. Then, the adjusted voltage has different values between the writing of State 0 and the writing of State 1 as can be understood from the fact that the curve C3 and the curve C4 are different. It can be understood that the MTJ voltage V_{MTJ} becomes equal to V_{c0} by applying the voltage adjusted in this manner to the memory cell 100 in the case where State 1 is to be written in State 0 and the case where State 0 is to be written in State 1 so that the magnetic anisotropy of the storage layer 124 becomes zero and writing of the opposite state is performed.

On the other hand, in the case where State 1 is to be written in State 1, the voltage at the intersection B becomes larger than V_{c0}, and the magnetic anisotropy of the storage layer 124 becomes negative. At this time, the magnetization of the storage layer 124 cannot perform desired precessional motion, and remains in State 1 after a pulse voltage is applied. That is, there is no erroneous change to State 0 unlike toggle writing. Further, in the case where State 0 is to be written in State 0, the voltage at the intersection D becomes lower than V_{c0}, and the magnetic anisotropy of the storage layer 124 remains positive. At this time, the magnetization of the storage layer 124 does not perform precessional motion, and remains in State 0 after the pulse voltage is applied. That is, there is no erroneous change to State 1 unlike the toggle writing. As described above, it can be understood that State 0 and State 1 can be written in a non-toggle manner regardless of an initial state.

Here, since the anisotropy is zero at each of the intersections A and C, precessional writing is possible. When a magnetization state changes due to the precessional motion, an operating point changes from A to B or from C to D. At the intersection B, an in-plane magnetization film is formed, and thus, writing is not possible due to precessional motion about a perpendicular axis. At the intersection D, a perpendicular magnetization film is formed, and thus, precessional motion does not occur and writing is not possible. Note that writing is not limited to the precessional motion, and may be, for example, a long pulse scheme.

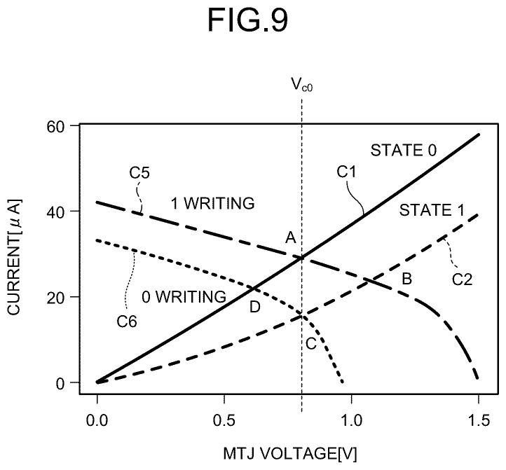

FIG. 9 is a view plotting a relationship between the MTJ voltage V_{MTJ} and the current flowing through the memory cell 100. Here, the curve C1 and the curve C2 are the same MTJ currents as those in FIG. 8. Further, a curve C5 represents a transistor current in the case of writing State 1, and a curve C6 represents a transistor current in the case of writing State 0. Here, the source line voltage V_{SL} is grounded, the word line voltage V_{WL} has the same value between the case of writing State 0 and the case of writing State 1 and the bit line voltage V_{BL} has different values between the case of writing State 0 and the case of writing State 1.

As can be seen from FIG. 7, the voltage V_{MTJ} applied to the MTJ by applying a voltage to the memory cell 100 becomes intersections of the curve C1, the curve C2, the curve C5, and the curve C6 since the MTJ current and the transistor current have the same value. Specifically, in a case where State 1 is to be written in State 0, a voltage indicated by an intersection A of the curve C1 and the curve C5 is applied to the MTJ. In a case where State 1 is to be written in State 1, a voltage indicated by an intersection B of the curve C2 and the curve C5 is applied to the MTJ. In a case where State 0 is to be written in State 1, a voltage indicated by an intersection C of the curve C2 and the curve C6 is applied to the MTJ. In a case where State 0 is to be written in State 0, a voltage indicated by an intersection D of the curve C1 and the curve C6 is applied to the MTJ. The voltages of the intersection A to the intersection D are in the same relationship as those in FIG. 8, and the bit line voltage V_{BL} is adjusted such that the voltages at the intersection A and the intersection C match the voltage V_{c0}. Then, the adjusted voltage has different values between the writing of State 0 and the writing of State 1 as can be understood from the fact that the curve C5 and the curve C6 are different. According to the same discussion as that in FIG. 8, State 0 and State 1 can be written in a non-toggle manner regardless of the initial state as described above.

### 1-5. Simulation Results

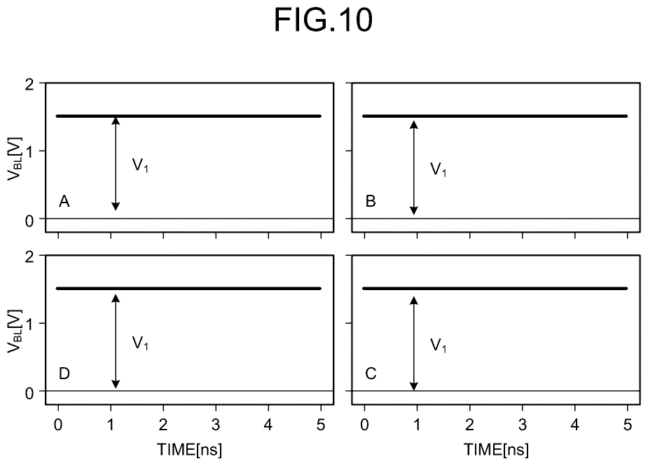

Simulation results according to the present embodiment will be described with reference to FIGS. 10 to 15.

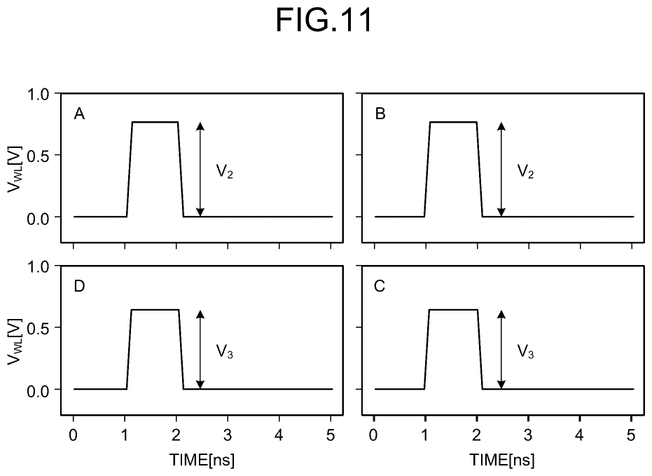

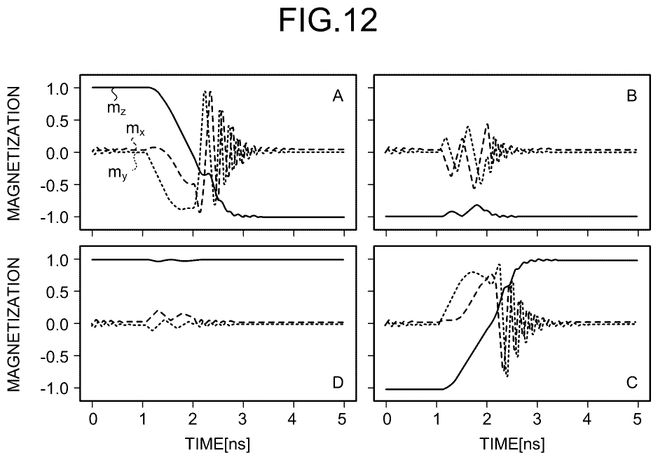

In FIGS. 10 to 12, the source line voltage V_{SL} is grounded as in FIG. 8, FIG. 10 is a view illustrating that the bit line voltage V_{BL} has the same value between the case of writing State 0 and the case of writing State 1, FIG. 11 is a view illustrating that the word line voltage V_{WL} has different values between the case of writing State 0 and the case of writing State 1, and FIG. 12 is a view illustrating simulation results of magnetization motion under conditions of FIGS. 10 and 11.

The respective drawings arranged in a 2×2 grid in FIGS. 10 to 12 correspond to the intersection A to the intersection D illustrated in FIG. 8. That is, the upper row corresponds to the case of writing State 1, the lower row corresponds to the case of writing State 0, the left column corresponds to a case where the initial state is State 0, and the right column corresponds to a case where the initial state is State 1. Further, in each drawing, the horizontal axis represents time, the vertical axis represents the bit line voltage V_{BL} in FIG. 10, the word line voltage V_{WL} in FIG. 11, and each axial component of magnetization of the storage layer 124 in FIG. 12. In FIG. 10, a constant voltage of V1 is applied as the bit line voltage V_{BL} in common between State 1 writing in the upper row and State 0 writing in the lower row. In FIG. 11, different voltages with a pulse of 1 ns, that is, V2 in State 1 writing in the upper row and V3 in State 0 writing in the lower row are applied as the word line voltage V_{WL}.

The magnetization motion when such voltages are applied is illustrated in FIG. 12. In a case indicated by A where State 1 is to be written when the initial state is State 0, a z-component of the magnetization is +1 before application of a pulse voltage, but is −1 after the application of the pulse, and it can be understood that a state change occurs. Similarly, in a case indicated by C where State 0 is to be written when the initial state is State 1, the z-component of the magnetization is −1 before the application of the pulse voltage, but is +1 after the application of the pulse, and it can be understood that a state change occurs. On the other hand, in cases indicated by B and D where the initial state and a state to be written are the same, the magnetization motion is observed during the application of the pulse, but it can be understood that the sign of the z-component of the magnetization is not changed before and after the application of the pulse voltage, and writing is not performed. In this manner, it can be understood that non-toggle writing can be performed by applying different voltages between the writing of State 0 and the writing of State 1 regardless of the initial state.

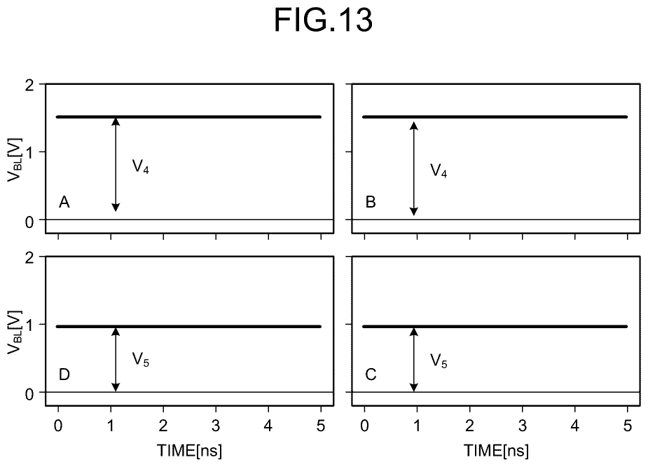

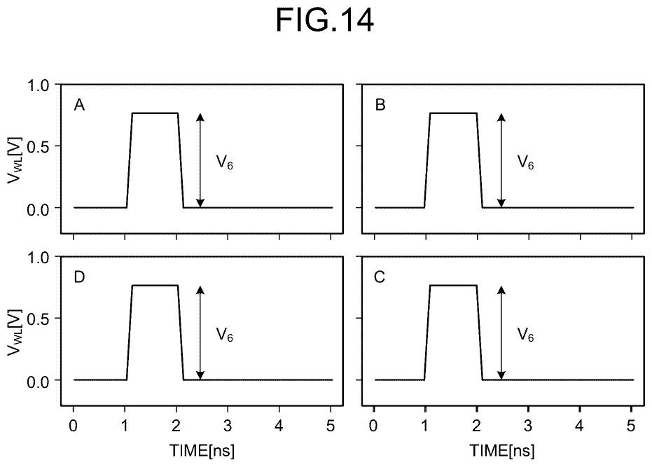

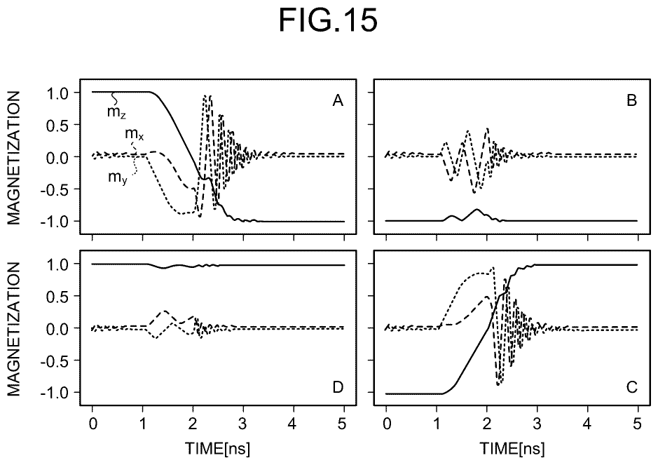

In FIGS. 13 to 15, the source line voltage V_{SL} is grounded as in FIG. 9, FIG. 13 is a view illustrating that the bit line voltage V_{BL} has different values between the case of writing State 0 and the case of writing State 1, FIG. 14 is a view illustrating that the word line voltage V_{WL} has the same value between the case of writing State 0 and the case of writing State 1, and FIG. 15 is a view illustrating simulation results of magnetization motion under conditions of FIGS. 13 and 14.

The respective drawings arranged in a 2×2 grid in FIGS. 13 to 15 correspond to the intersection A to the intersection D illustrated in FIG. 9. That is, the upper row corresponds to the case of writing State 1, the lower row corresponds to the case of writing State 0, the left column corresponds to a case where the initial state is State 0, and the right column corresponds to a case where the initial state is State 1. Further, in each drawing, the horizontal axis represents time, the vertical axis represents the bit line voltage V_{BL} in FIG. 13, the word line voltage V_{WL} in FIG. 14, and each axial component of magnetization of the storage layer 124 in FIG. 15. In FIG. 13, different constant voltages, that is, V4 in State 1 writing in the upper row and V5 in State 0 writing in the lower row are applied as the bit line voltage V_{BL}. In FIG. 14, a common voltage V6 with a pulse of 1 ns is applied as the word line voltage V_{WL} in State 1 writing in the upper row and in State 0 writing in the lower row. The magnetization motion when such voltages are applied is illustrated in FIG. 15. The non-toggle writing is performed by applying different voltages between the writing of State 0 and the writing of State 1 regardless of the initial state, which is similar to the magnetization motion illustrated in FIG. 12 although details are different.

Note that the bit line voltage V_{BL} is a constant voltage and the word line voltage V_{WL} is a pulse voltage in FIGS. 10 to 15, but conversely, the bit line voltage V_{BL} may be a pulse voltage and the word line voltage V_{WL} may be a constant voltage. Further, both the bit line voltage V_{BL} and the word line voltage V_{WL} may be pulse voltages. At this time, a rise or a fall of a pulse voltage may or does not necessarily match between the bit line voltage V_{BL} and the word line voltage V_{WL}. Further, although a pulse width is 1 ns, this is merely an example, and any pulse width can be adopted as long as writing can be performed correctly.

### 1-6. Write Processing

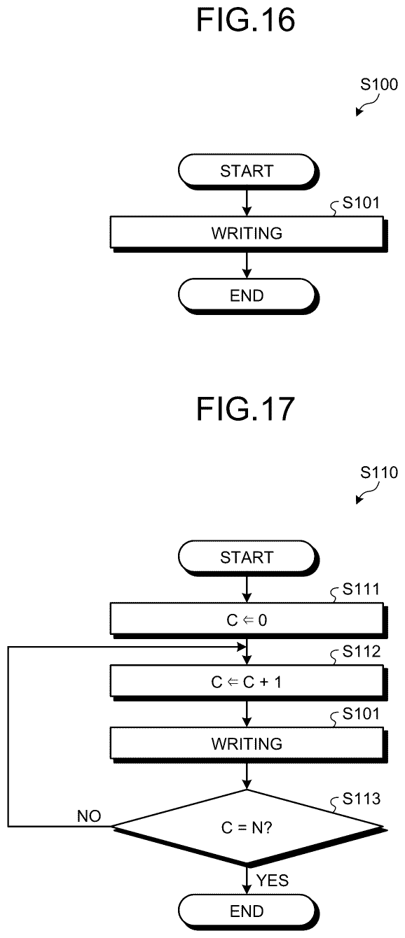

Write processing according to the present embodiment will be described with reference to FIGS. 16 to 21.

FIG. 16 is a view illustrating a first example of a processing procedure of the write processing according to the present embodiment. The drawing is a flowchart illustrating an example of write processing (step S100) in the memory system 1. As illustrated in FIG. 16, the write circuit 70 performs writing (step S101). Through the above processing, the writing can be performed.

FIG. 17 is a diagram illustrating a second example of the processing procedure of the write processing according to the present embodiment. The drawing is a flowchart illustrating an example of write processing (step S110) in the memory system 1. As illustrated in FIG. 17, first, a counter C held in the memory control unit 3 is set to zero (step S111). Next, one is added to the counter C held in the memory control unit 3 (step S112). Next, the write circuit 70 performs writing (step S101). Thereafter, the memory control unit 3 determines whether a value of the counter C matches a number N of continuous write times determined in advance (step S113). As a result, in a case of matching the number N of continuous write times (Yes in step S113), the processing is ended. On the other hand, in a case of not matching the number N of continuous writing in step S113 (No in step S113), the processing from step S112 is performed again. Through the above processing, continuous writing can be performed.

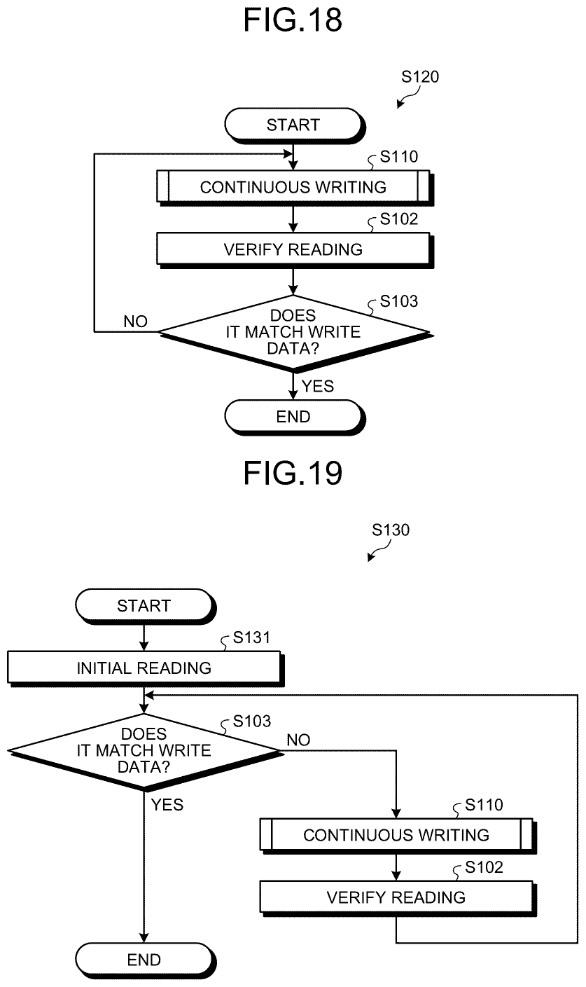

FIG. 18 is a diagram illustrating a third example of the processing procedure of the write processing according to the present embodiment. The drawing is a flowchart illustrating an example of write processing (step S120) in the memory system 1. As illustrated in FIG. 18, first, the continuous write processing illustrated in FIG. 17 is performed (step S110). Next, the read circuit 80 performs verify reading from the target memory cell 100 (step S102). Next, it is determined whether data read by the memory control unit 3 matches write data (step S103). As a result, in a case of matching the write data (Yes in step S103), the processing is ended. On the other hand, in step S103, in a case of not matching the write data (No in step S103), the processing from step S110 is performed again. Through the above processing, continuous writing with a verification function can be performed.

FIG. 19 is a diagram illustrating a fourth example of the processing procedure of the write processing according to the present embodiment. The drawing is a flowchart illustrating an example of write processing (step S130) in the memory system 1. As illustrated in FIG. 19, first, the read circuit 80 performs initial reading from the target memory cell 100 (step S131). Next, it is determined whether data read by the memory control unit 3 matches write data (step S103). As a result, in a case of matching the write data (Yes in step S103), the processing is ended. On the other hand, in a case of not matching the write data in step S103 (No in step S103), the continuous write processing illustrated in FIG. 17 is performed (step S110). Next, the read circuit 80 performs verify reading (step S102). Thereafter, the processing from step S103 is performed again. Through the above processing, it is possible to perform continuous writing with a verification function that involves initial reading.

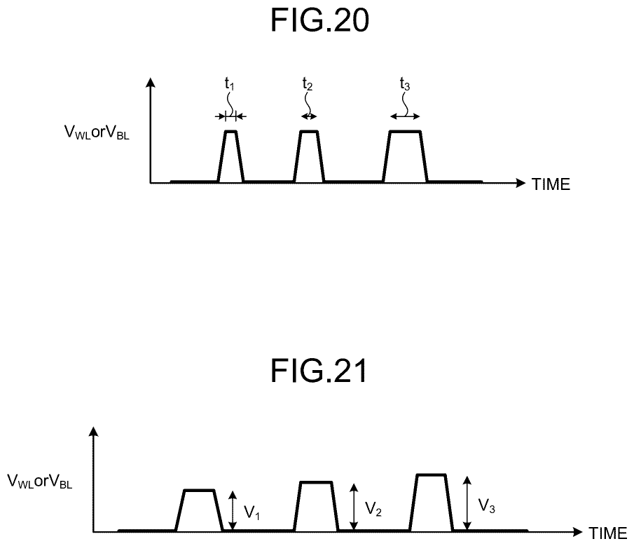

FIGS. 20 and 21 are views for describing a continuous write method according to the present embodiment. Each drawing illustrates a variation of a method for applying a pulse voltage in the continuous write processing illustrated in FIG. 17. In FIG. 20, a pulse width of the pulse voltage in each writing is different (t₁<t₂<t₃). On the other hand, in FIG. 21, a voltage value (amplitude) of the pulse voltage in each writing is different (V₁<V₂<V₃). Since the optimum write pulse width and voltage may vary among the magnetoresistive elements 120 in the memory cell array 10, it is possible to reduce a write error rate by performing writing with different pulse widths and voltages a plurality of times.

Note that three pulses are applied in examples of FIGS. 20 and 21, but the number of times of applying a pulse is arbitrary. Further, not only one of the pulse width and the voltage value (amplitude) of the pulse voltage but also both of them in each writing may be different. Further, the pulse voltage is desirably a pulse voltage having a pulse width of 0.1 ns or more and 20 ns or less. The precessional motion reliably occurs if the pulse width is 0.1 ns or more, the precessional motion converges (stabilizes) if the pulse width is 20 ns or less, but the precessional motion ends as the magnetization is completely oriented in an external magnetic field direction if the pulse width exceeds 20 ns.

### 1-7. Write Scheme Using Non-Rectangular Pulse

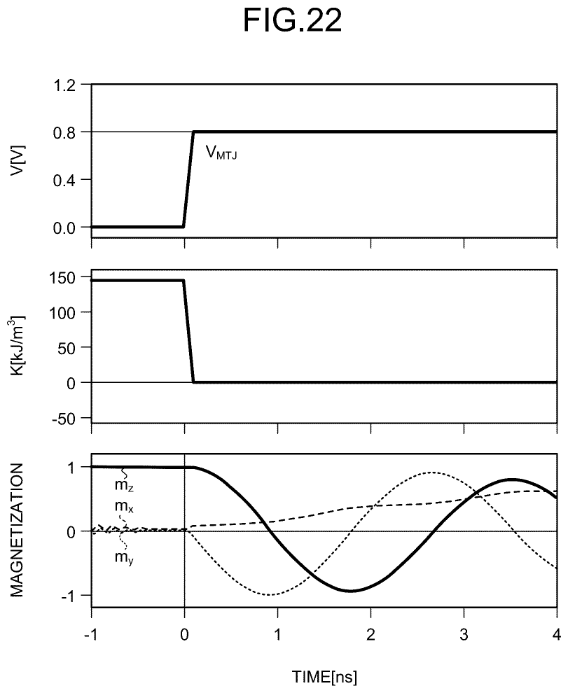

A write scheme using a non-rectangular pulse according to the present embodiment will be described with reference to FIGS. 22 to 33.

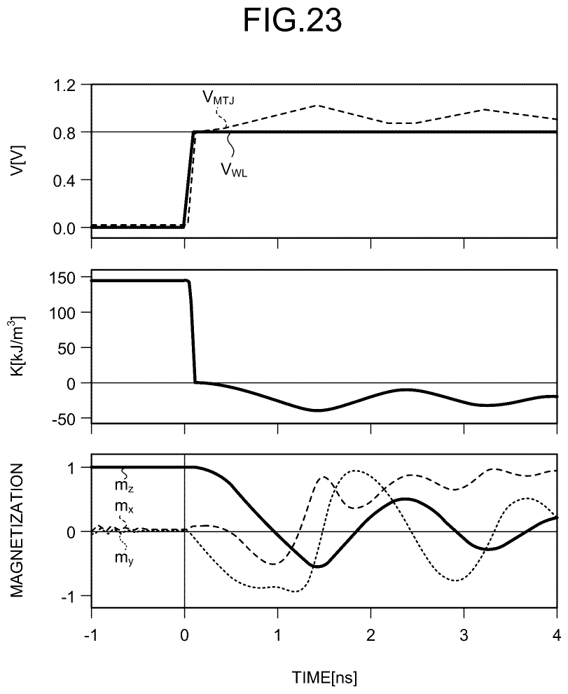

In the above description, a shape of a write pulse is a rectangular pulse as illustrated in FIG. 11. The term “rectangular” means that a voltage of the write pulse is substantially constant. Simulation results of magnetization motion when the rectangular pulse is used are illustrated in FIGS. 22 and 23. For comparison, FIG. 22 illustrates the case of the MTJ alone, and FIG. 23 illustrates the case of the memory cell 100 of the present embodiment. The upper row illustrates a voltage, the middle row illustrates perpendicular magnetic anisotropy energy K, and the lower row illustrates magnetization. In the MTJ of FIG. 22, the voltage V_{c0} is directly applied to the MTJ. In the memory cell 100 of FIG. 23, the word line voltage V_{WL} is adjusted such that the voltage V_{c0} is applied to the MTJ. In both the cases, the above-described voltages are continuously applied from time 0 ns after relaxation time of 1 ns.

In FIG. 22, K=0 is maintained since the MTJ voltage V_{MTJ} is fixed. As a result, the magnetization motion illustrated in the lower row is ideal precessional motion in a spiral form with a constant cycle. On the other hand, in the memory cell 100 of FIG. 23, the word line voltage V_{WL} is fixed, but the MTJ voltage V_{MTJ} is a value obtained by dividing the bit line voltage by the MTJ and the selection element 110, and thus, is not constant.

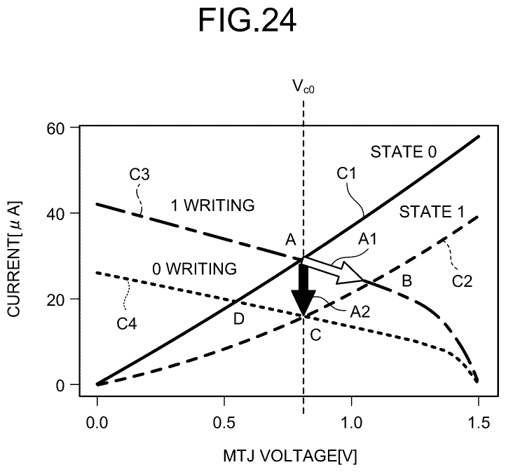

Specifically, the MTJ voltage V_{MTJ} is interlocked with the magnetization motion as indicated by a broken line in the upper row of FIG. 23. Since the magnetization is in State 0 at the time 0 ns, V_{c0} is applied to the MTJ as assumed. However, once the magnetization motion starts, the magnetization deviates from State 0. A resistance value R of the MTJ depends on a perpendicular component of the magnetization of the storage layer 124. An intersection of an MTJ current determined by the resistance value and a transistor current becomes a new operating point. This state is indicated by an arrow A1 in FIG. 24. The MTJ current moves between State 0 and State 1 in accordance with the magnetization motion, and the operating point moves between A and B.

The time dependency of K is illustrated in the middle row of FIG. 23. Although K=0 at the start of voltage application, the MTJ voltage becomes higher than V_{c0} due to an increase in resistance. Since the perpendicular magnetic anisotropy is neither zero nor constant but takes a negative value, the storage layer 124 forms an in-plane magnetization layer. Since not only an external magnetic field but also an effective magnetic field pulling the magnetization within the plane acts, the magnetization motion illustrated in the lower row of FIG. 23 is not the ideal precessional motion in the spiral form but is distorted. In the magnetization motion in the lower row of FIG. 22, a z-component of the magnetization has a minimum value at about 1.9 ns. An absolute value thereof is 0.93. In the magnetization motion in the lower row of FIG. 23, the z-component of the magnetization has a minimum value at about 1.4 ns. An absolute value thereof is 0.54. As the absolute value of the minimum is closer to one, writing can be more stably performed when the voltage application is stopped at that time. For this reason, the stability of writing tends to decrease in writing using the memory cell 100 as compared with writing using the MTJ alone.

In order to eliminate such instability of writing, it is possible to use a voltage pulse having a non-rectangular shape in writing according to the present embodiment. FIG. 24 illustrates a concept thereof. With the rectangular pulse, there is a problem that the MTJ voltage increases and the perpendicular magnetic anisotropy is not zero when the operating point moves from A to B. Therefore, the operating point is then moved from A to C. Accordingly, the MTJ voltage remains at V_{c0} even during the magnetization motion, and the perpendicular magnetic anisotropy is also maintained at zero.

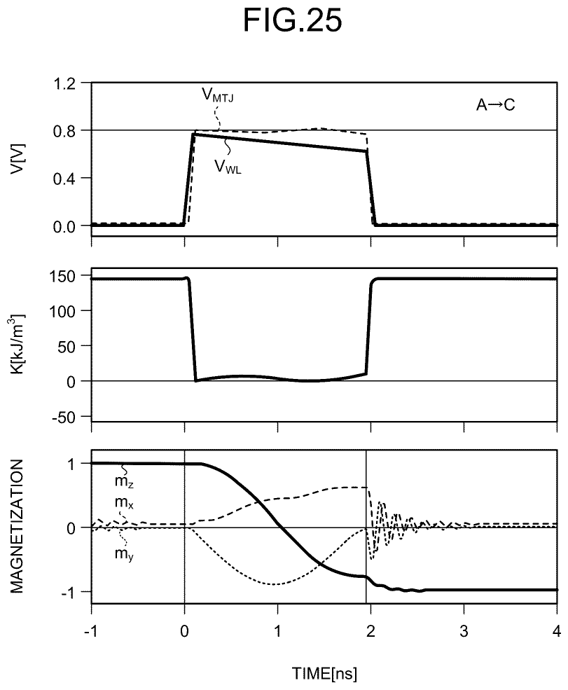

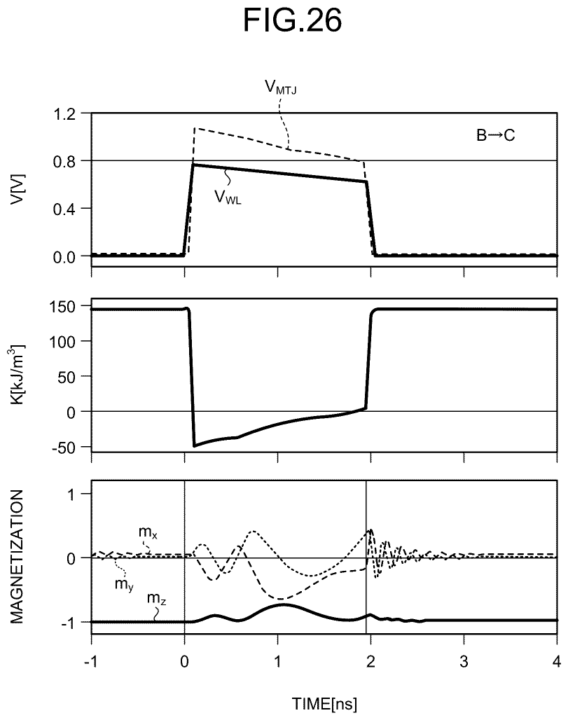

FIGS. 25 and 26 illustrate simulation results of writing of State 1. The initial state is State 0 in FIG. 25, and the initial state is State 1 in FIG. 26. The MTJ voltage in the upper row of FIG. 25 is substantially constant, and K in the middle row is substantially zero. As a result, the ideal precessional motion is achieved. In the lower row, an absolute value of the z-component of the magnetization at 1.9 ns when the voltage pulse ends is 0.79. Since the value is 0.54 when the rectangular pulse is used, it can be understood that the stability of writing is improved. Further, magnetization reversal does not occur in FIG. 26. That is, the non-toggle writing can be implemented as in the case of the rectangular pulse.

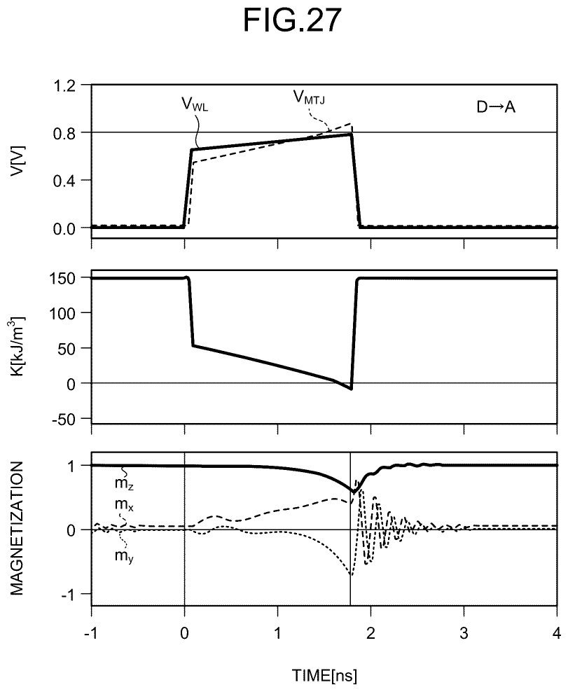

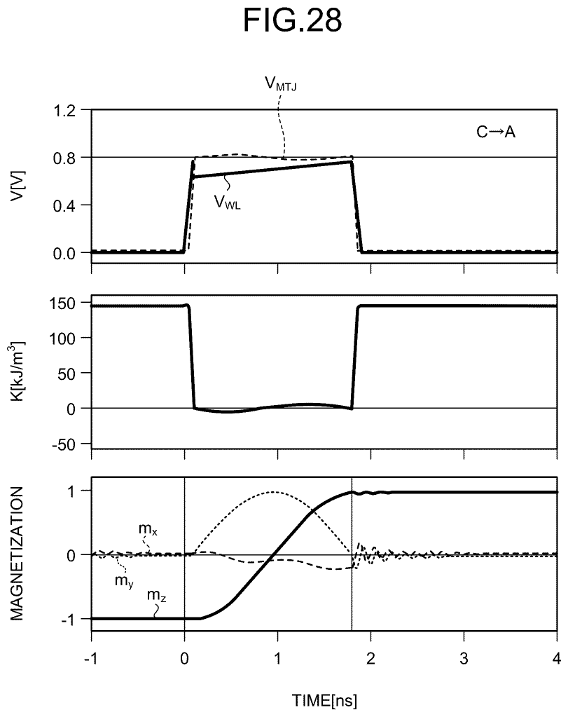

Similarly, simulation results of writing of State 0 are illustrated in FIGS. 27 and 28. The initial state is State 0 in FIG. 27, and the initial state is State 1 in FIG. 28. The MTJ voltage in the upper row of FIG. 28 is substantially constant, and K in the middle row is substantially zero. As a result, the ideal precessional motion is achieved. In the lower row, an absolute value of the z-component of the magnetization at 1.7 ns when the voltage pulse ends is 0.99, and it can be understood that the stability of writing is improved. Further, magnetization reversal does not occur in FIG. 27. That is, the non-toggle writing can be implemented as in the case of the rectangular pulse.

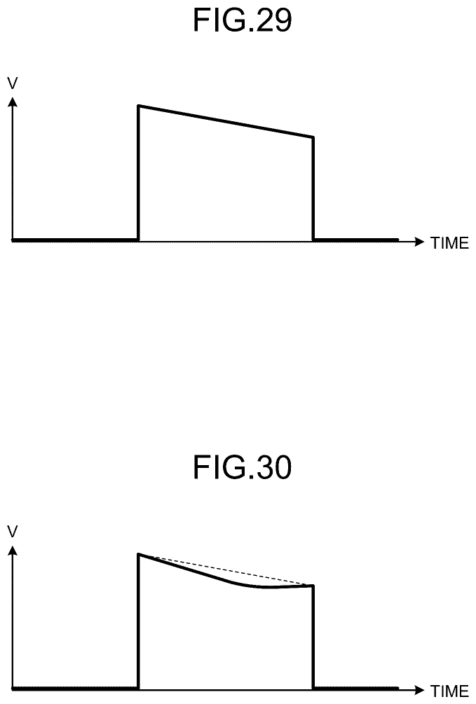

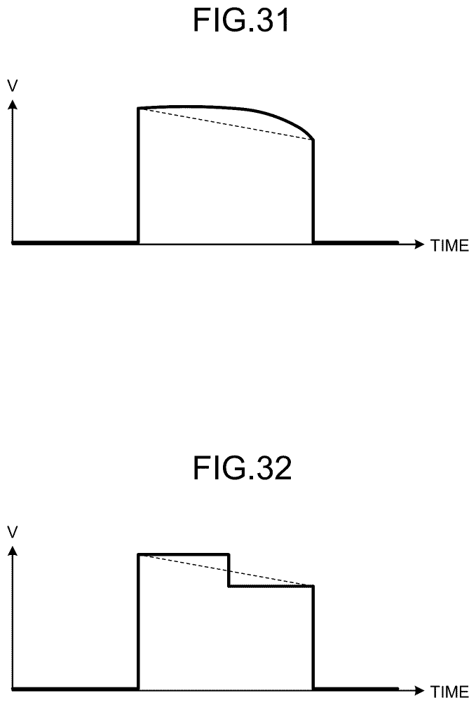

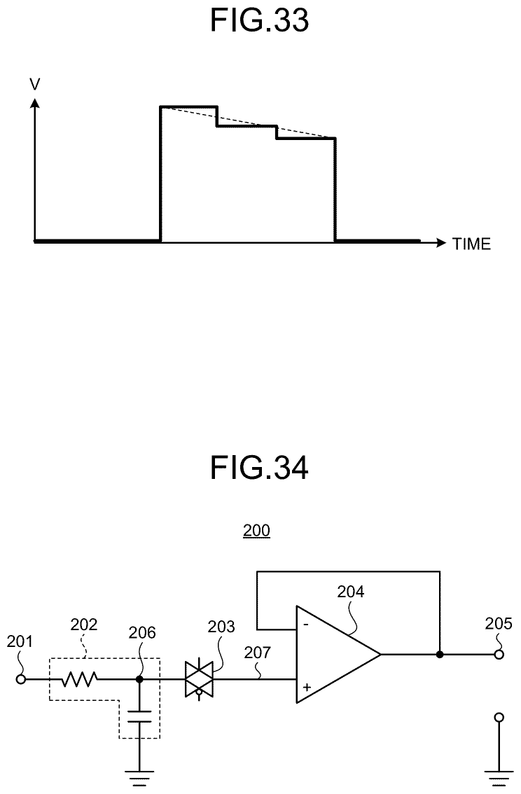

FIGS. 29 to 33 are views each illustrating an example of a shape of a non-rectangular pulse. Note that FIGS. 29 to 33 illustrate the case of writing of State 1. In the case of writing of State 0, a voltage increases with time. In FIG. 29, a voltage shape linearly depends on time. In FIG. 30, a voltage shape protrudes downward. In FIG. 31, a voltage shape protrudes upward. In each of FIGS. 32 and 33, a voltage shape is formed into a non-rectangular pulse including a plurality of rectangular pulses. The above FIGS. 29 to 33 illustrate the examples of the shape of the non-rectangular pulse, and the shape is not limited thereto.

Here, in each of FIGS. 29 to 33, a pulse waveform has a shape in which the amplitude changes from zero to a desired amplitude value, gradually decreases from the desired amplitude value to the other amplitude value, and changes from the other amplitude values to zero. This pulse waveform has the shape that decreases linearly, curvilinearly, or stepwise from the desired amplitude value to the other amplitude value. This shape corresponds to the case of writing of State 1, and in the case of writing of State 0, a pulse waveform has a shape that increases linearly, curvilinearly, or stepwise from a desired amplitude value to another amplitude value.

### 1-8. Write Pulse Generation Circuit

Write pulse generation circuits 200 and 210 according to the present embodiment will be described with reference to FIGS. 34 to 37. Each of the write pulse generation circuits 200 and 210 generates a write pulse (pulse voltage). The write pulse generation circuit 200 and/or 210 is included in the write circuit 70, for example.

FIG. 34 is a diagram illustrating a configuration example of the write pulse generation circuit 200. As illustrated in FIG. 34, the write pulse generation circuit 200 includes a CR circuit 202, a transfer gate 203, and a negative feedback amplifier circuit using an operational amplifier 204. The transfer gate 203 controls conduction and interruption between an output 206 of the CR circuit 202 and a non-inverting input 207 of the operational amplifier 204.

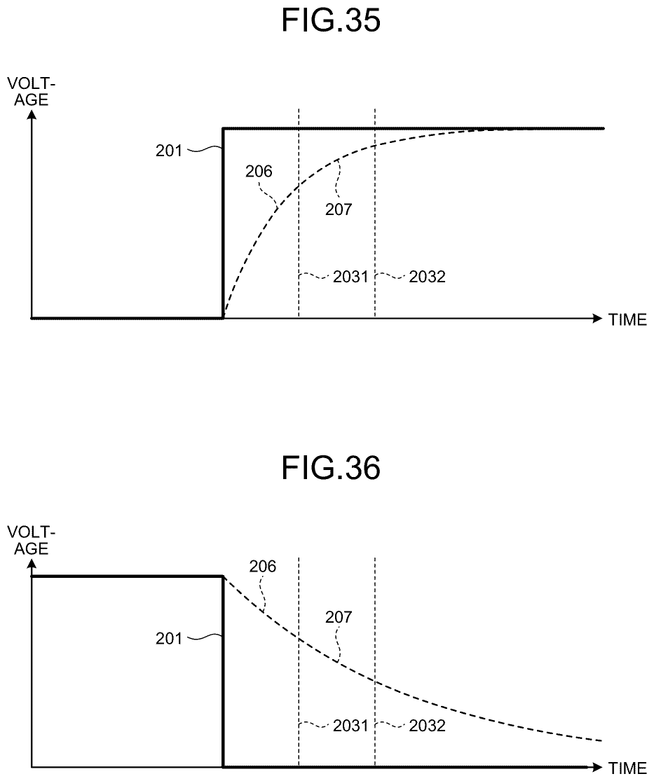

FIGS. 35 and 36 are views each illustrating an operation example of the write pulse generation circuit 200 illustrated in FIG. 34. In FIG. 35, a rectangular rising voltage is input to an input end 201 of the write pulse generation circuit 200. A rectangular signal input to the input end 201 has a waveform with a smooth rise time by the CR circuit 202. The transfer gate 203 allows the conduction between the output 206 of the CR circuit 202 and the non-inverting input 207 of the operational amplifier 204 only from time 2031 to time 2032. The negative feedback amplifier circuit outputs a signal corresponding to a difference between a signal input to a non-inverting input terminal and a negative feedback signal input to an inverting input terminal, as the write pulse, from an output terminal 205.

In FIG. 36, a rectangular falling voltage is input to the input end 201 of the write pulse generation circuit 200. A rectangular signal input to the input end 201 has a waveform with a smooth fall time by the CR circuit 202. The transfer gate 203 allows the conduction between the output 206 of the CR circuit 202 and the non-inverting input 207 of the operational amplifier 204 only from time 2031 to time 2032. The negative feedback amplifier circuit outputs a signal corresponding to a difference between a signal input to the non-inverting input terminal and a negative feedback signal input to the inverting input terminal, as the write pulse, from the output terminal 205.

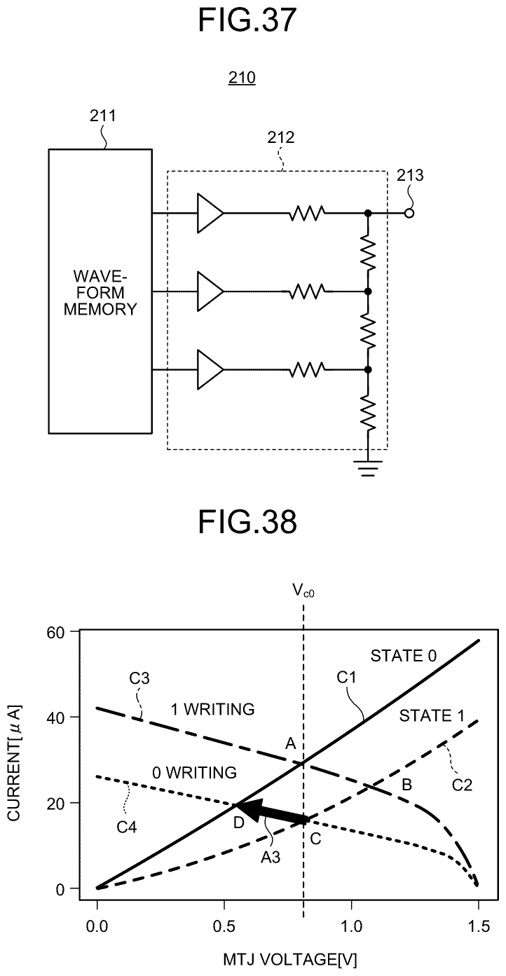

FIG. 37 is a diagram illustrating another configuration example of the write pulse generation circuit 210. As illustrated in FIG. 37, the write pulse generation circuit 210 includes a waveform memory 211 and a D/A conversion circuit 212. This write generation circuit 210 generates the write pulse using the waveform memory 211 and the D/A conversion circuit 212.

The waveform memory 211 stores waveform data of the write pulse. The waveform data of the write pulse includes time-series data of a plurality of words with N bits whose output level can be selected from among 2N steps as one word. N ports for reading are provided in the waveform memory 211, and these N ports are connected to N input ends, respectively, of the D/A conversion circuit 212.

The D/A conversion circuit 212 inputs the waveform data of the write pulse from the waveform memory 211 for each N-bit data (one word), converts the data into an analog signal, and outputs the analog signal as the write pulse. The D/A conversion circuit 212 can be configured using, for example, a ladder resistor circuit or the like.

Since such write pulse generation circuits 200 and 210 are used, a waveform of the write pulse can be obtained with a high degree of freedom, and the write pulse of each of the above embodiments can be easily obtained with a high degree of freedom. Note that, in the example of FIG. 37, the number N of bits of one word is set to “3” such that the output level can be determined from among 23 levels, but this number is not particularly limited.

### 1-9. Write Scheme Using Rectangular Long Pulse

A write scheme using a rectangular long pulse according to the present embodiment will be described with reference to FIGS. 38 to 42.

As described above, the non-toggle writing can be performed by applying a rectangular or non-rectangular pulse to the memory cell 100. However, it is desirable to control a pulse width of the rectangular or non-rectangular pulse with high accuracy in order to write in a desired state. Unless the pulse width of the rectangular or non-rectangular pulse is controlled with high accuracy, for example, there is a concern that precessional motion of magnetization proceeds beyond a half turn and returns to a state before the writing.

Meanwhile, in the writing using the memory cell 100 according to the present embodiment illustrated in FIG. 7, it is clear from the simulation results that it is unnecessary to control the pulse width of the rectangular pulse only for the writing of State 0. FIG. 38 illustrates a concept thereof. As illustrated in FIG. 38, the operating point moves from C to D as indicated by an arrow A3 in the case of writing of State 0. Then, the MTJ voltage decreases, the perpendicular magnetic anisotropy becomes positive, and the precessional motion stops automatically. That is, it is unnecessary to limit the pulse width of the write pulse to, for example, 1.6 ns. Such a pulse that only needs to be a certain time (for example, 1 ns) or more without any limitation to the pulse width is referred to as a “long pulse”. Further, the operating point is at D when the initial state is State 0. At this time, the perpendicular magnetic anisotropy remains positive, and thus, the precessional motion does not occur. That is, no matter how long the write pulse is applied, no state change occurs.

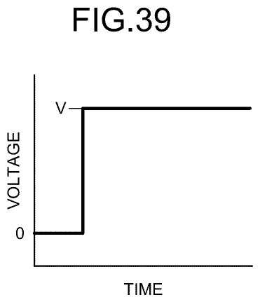

As an example of such a write pulse, a rectangular long pulse is used. As illustrated in FIG. 39, a shape of the rectangular long pulse is a shape in which a termination voltage of a rectangular pulse is maintained as it is without being set to zero. Specifically, the shape of the rectangular long pulse is a shape in which the amplitude changes from zero to a desired amplitude value and the desired amplitude value is maintained until a termination of a pulse waveform.

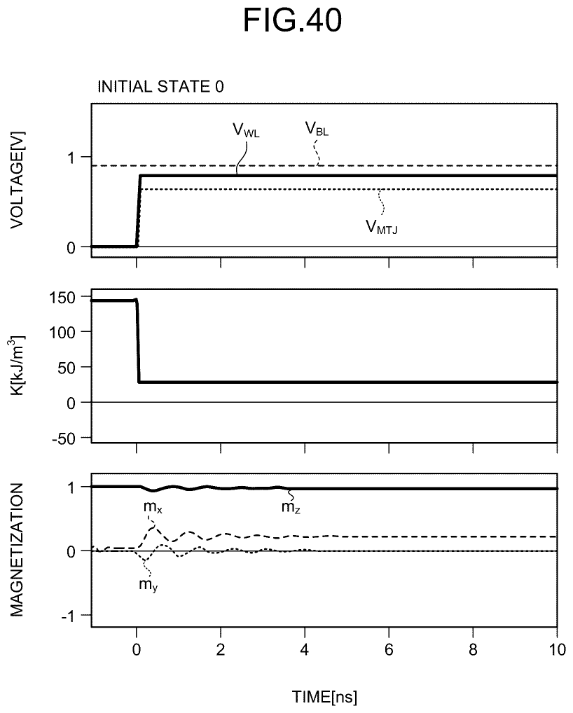

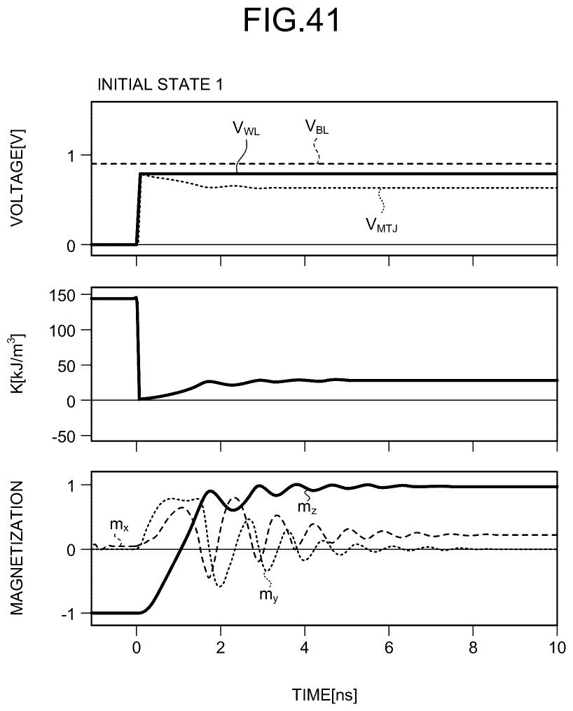

FIGS. 40 and 41 illustrate simulation results of the writing of State 0. The initial state is State 0 in FIG. 40, and the initial state is State 1 in FIG. 41. Since K in the middle row of FIG. 40 is positive from the start to the end, magnetization reversal does not occur. K in the middle row of FIG. 41 is substantially zero at the start of voltage application, but increases as a state change occurs due to the precessional motion and becomes a positive value. After State 0 is written as a result, the precessional motion stops automatically. That is, the writing of State 0 can be implemented in a non-toggle manner by applying the rectangular long pulse.

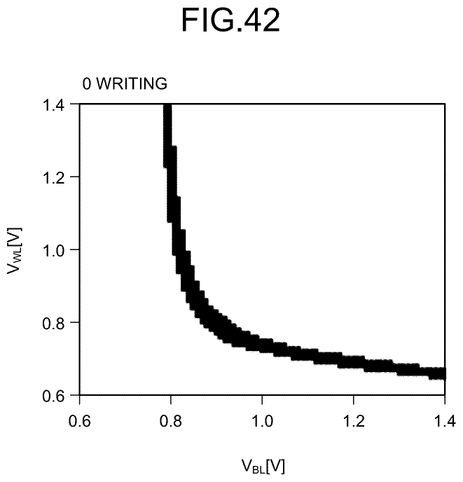

Note that, in the writing of State 0 using the rectangular long pulse, there is no constraint for the pulse width of the write pulse, but there is a constraint for a pulse amplitude. The bit line voltage V_{BL} and the word line voltage V_{WL} of the memory cell 100 illustrated in FIG. 7 were varied by a grid, and a simulation similar to that in FIGS. 40 and 41 was performed to obtain combinations of the bit line voltage V_{BL} and the word line voltage V_{WL} that enable writing in a non-toggle manner. FIG. 42 illustrates results thereof. A black strip-shaped portion is a portion indicating the combinations of the bit line voltage V_{BL} and the word line voltage V_{WL} that enable the non-toggle writing. As can be seen from FIG. 42, a region of the portion is narrow, and a width thereof is only about 60 mV at the maximum. This means that the pulse amplitude of the write pulse needs to be controlled to this extent. An embodiment in which the non-toggle writing can be expanded will be described in <1-11> below.

### 1-10. Write Scheme Using Gradient Long Pulse

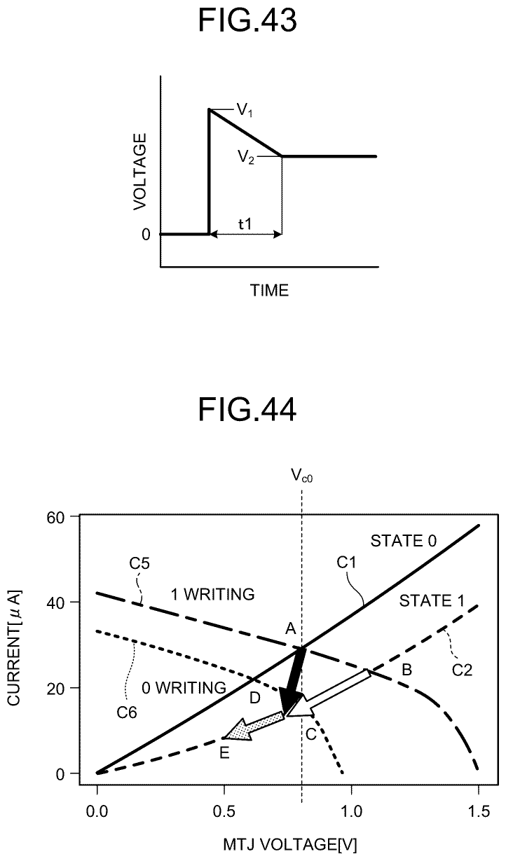

A write scheme using a gradient long pulse according to the present embodiment will be described with reference to FIGS. 43 to 48.

FIG. 43 is a view illustrating an example of a shape of the gradient long pulse. Note that FIG. 43 illustrates the case of writing of State 1. That is, the shape of the gradient long pulse is a shape in which a termination voltage of the non-rectangular pulse illustrated in FIG. 29 is maintained as it is without being set to zero. Specifically, the shape of the gradient long pulse is a shape in which the amplitude changes from zero to a desired amplitude value (first amplitude value), gradually decreases from the desired amplitude value to a next desired amplitude value (second amplitude value), and maintains the next desired amplitude value until a termination of a pulse waveform.

Note that FIG. 43 illustrates the example of the shape of the gradient long pulse, and the shape is not limited thereto. For example, the shape can also be a shape in which a termination voltage of the non-rectangular pulse illustrated in any one of FIGS. 30 to 33 is maintained as it is without being set to zero. That is, the shape of the gradient long pulse is a shape in which the amplitude gradually decreases from a desired amplitude value linearly, curvilinearly, or stepwise to a next desired amplitude value. This shape corresponds to the case of writing of State 1, and in the case of writing of State 0, a shape of the gradient long pulse is a shape in which the amplitude gradually increases from a desired amplitude value linearly, curvilinearly, or stepwise to a next desired amplitude value.

When the gradient long pulse illustrated in FIG. 43 is used in the writing of State 1, a constraint for a pulse width is eliminated. FIG. 44 illustrates a concept thereof. The operating point is moved from A not to C but further to E by extending a slope of a non-rectangular pulse. Then, at the operating point E, the MTJ voltage decreases, the perpendicular magnetic anisotropy becomes positive, and the precessional motion stops automatically. That is, it is unnecessary to limit the pulse width of the write pulse to, for example, 1.6 ns.

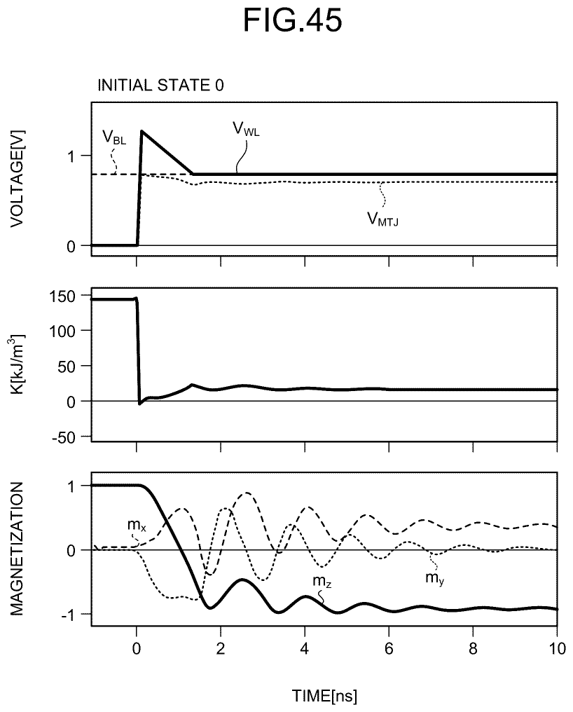

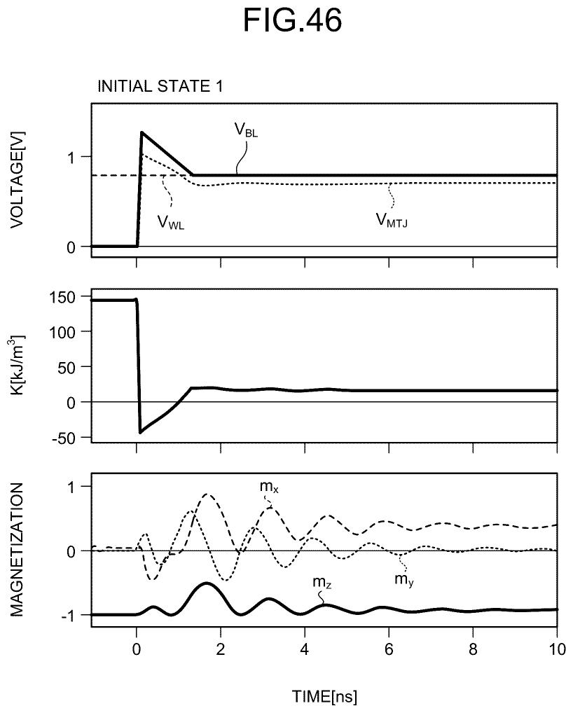

FIGS. 45 and 46 illustrate simulation results of the writing of State 1. The initial state is State 0 in FIG. 45, and the initial state is State 1 in FIG. 46. K in the middle row of FIG. 45 is substantially zero at the start of voltage application, but increases as a state change occurs due to the precessional motion and becomes a positive value. After State 1 is written as a result, the precessional motion stops automatically. K in the middle row of FIG. 46 is negative at the start of voltage application, and desired precessional motion cannot be performed. Thereafter, K exceeds zero and becomes a positive value as the MTJ voltage decreases, and the magnetization motion stops. That is, the writing of State 1 can be implemented in a non-toggle manner by applying the gradient long pulse.

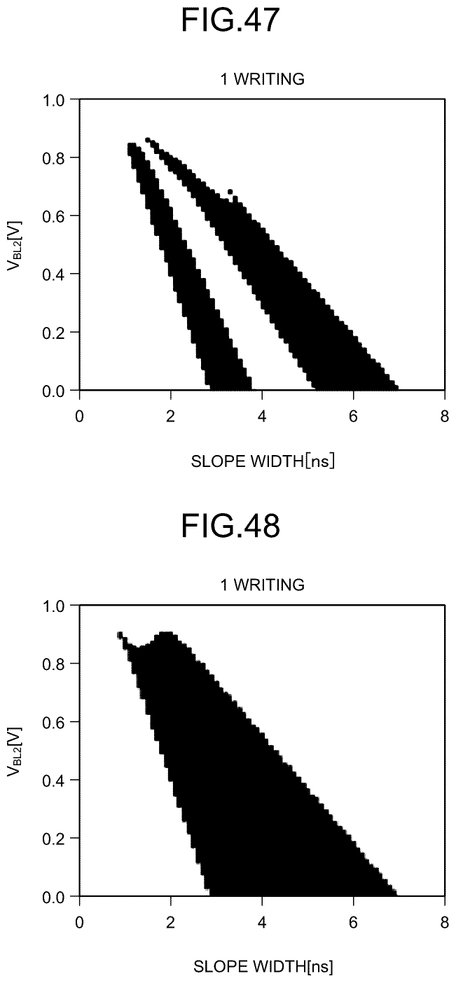

A constraint for the shape of the gradient long pulse was simulated as in the write scheme using the rectangular long pulse of <1-9> described above. The shape of the gradient long pulse includes a starting voltage V₁, a termination voltage V₂, and a slope width t1 illustrated in FIG. 43. Among them, the starting voltage V₁ was fixed to a voltage value at which the perpendicular magnetic anisotropy energy K becomes zero for State 0. The remaining termination voltage V₂ and slope width t1 were varied by a grid. Note that there are a case where the bit line BL is used and a case where the word line WL is used when a voltage pulse is applied to the memory cell 100. Since the bit line BL is used here, simulation results using the termination voltage V₂ as the bit line voltage V_{BL2} are illustrated in FIGS. 47 and 48. A black strip-shaped portion in FIG. 47 is a region where the writing of State 1 is successful regardless of the initial state, and a black strip-shaped portion in FIG. 48 is a region where the writing of State 1 is successful only when the initial state is State 0.

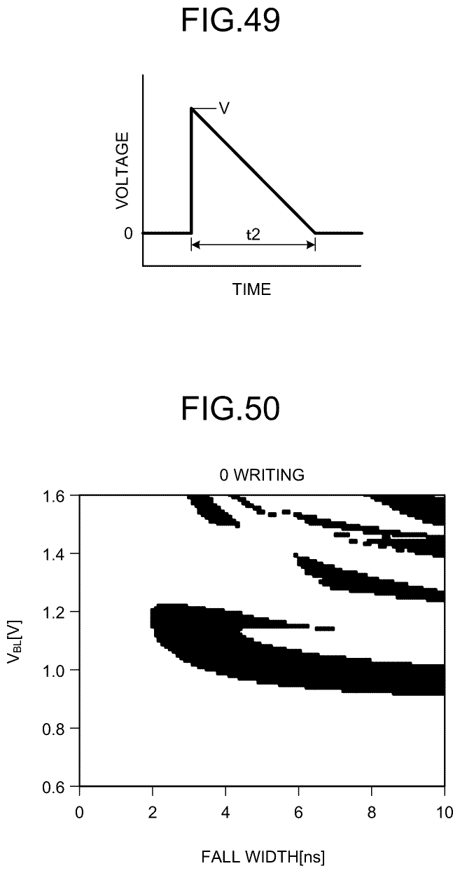

As can be seen from FIGS. 47 and 48, it can be understood that the slope width t1 at which the writing is successful is wider as the bit line voltage V_{BL2} of the slope is lower. Then, it can be understood that a case where the bit line voltage V_{BL2} is zero is most desirable. A pulse shape at this time is a “falling type sawtooth pulse” illustrated in FIG. 49. A write scheme using a sawtooth pulse will be described in <1-11> below. Further, when FIGS. 47 and 48 are compared, the region where the writing is successful is wider when the initial state is limited to State 0. For this reason, when the initial state is State 1, it is possible to use a scheme of writing State 0 before writing State 1, and then writing State 1. This scheme will be described in <1-12> below.

### 1-11. Write Scheme Using Sawtooth Pulse

The write scheme using the sawtooth pulse according to the present embodiment will be described with reference to FIGS. 49 to 57.

FIG. 49 is a view illustrating an example of a shape of the falling type sawtooth pulse. The shape of the falling type sawtooth pulse is a shape in which the termination voltage of the non-rectangular pulse illustrated in FIG. 29 is set to zero. Specifically, the shape of the falling type sawtooth pulse is a shape in which the amplitude changes from zero to a desired amplitude value and gradually decreases from the desired amplitude value to zero. Note that FIG. 49 illustrates the example of the shape of the falling type sawtooth pulse, and the shape is not limited thereto. For example, the shape can also be a shape in which the termination voltage of the non-rectangular pulse illustrated in any one of FIGS. 30 to 33 is set to zero. That is, the shape of the falling type sawtooth pulse is a shape in which the amplitude changes from zero to a desired amplitude value, and the amplitude gradually decreases from the desired amplitude value linearly, curvilinearly, or stepwise to zero.

A constraint for the shape of the falling type sawtooth pulse was simulated as in the write scheme using the gradient long pulse of <1-10> described above. The shape of the falling type sawtooth pulse includes a starting voltage V and a fall width t2 illustrated in FIG. 49. The starting voltage V and the fall width t2 were varied by a grid. Note that there are a case where the bit line BL is used and a case where the word line WL is used when a voltage pulse is applied to the memory cell 100. Since the bit line BL is used here, simulation results using the starting voltage V as the bit line voltage V_{BL} are illustrated in FIG. 50. A black strip-shaped portion in FIG. 50 is a region where writing of State 0 is successful regardless of the initial state. It can be understood that the bit line voltage V_{BL} that enables the non-toggle writing exists when the fall width is 2 ns or more. For example, when the fall width t2 is 10 ns, a width of the bit line voltage V_{BL} is about 90 mV. Since the width of the bit line voltage V_{BL} in the case of the rectangular long pulse illustrated in FIG. 42 is 60 mV, it can be understood that an operation margin of 1.5 times is obtained.

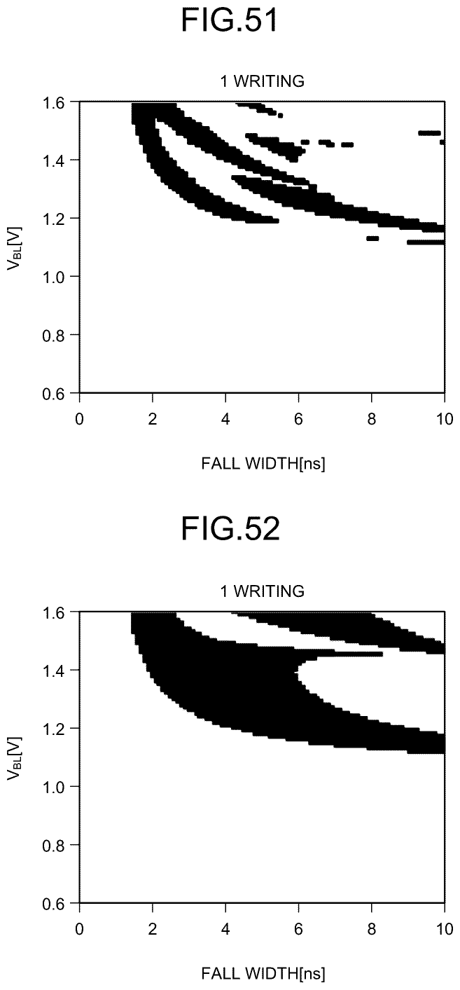

Further, simulation results in the case of writing of State 1 are illustrated in FIGS. 51 and 52. A black strip-shaped portion in FIG. 51 is a region where the writing of State 1 is successful regardless of the initial state, and a black strip-shaped portion in FIG. 52 is a region where the writing of State 1 is successful only when the initial state is State 0. Further, when FIGS. 51 and 52 are compared, the region where the writing is successful is wider when the initial state is limited to “0”. For this reason, when the initial state is State 1, it is possible to use a scheme of writing State 0 before writing State 1, and then writing State 1. This scheme will be described in <1-12> below.

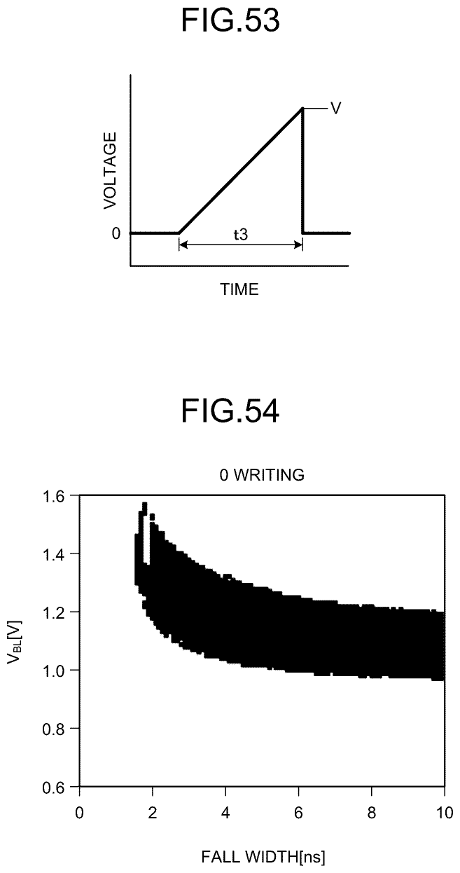

FIG. 53 is a view illustrating an example of a shape of a rising type sawtooth pulse. That is, the shape of the rising type sawtooth pulse is a shape obtained by inverting the non-rectangular pulse illustrated in FIG. 49 on the time axis. Specifically, the shape of the rising type sawtooth pulse is a shape in which the amplitude gradually increases from zero to a desired amplitude value, and changes from the desired amplitude value to zero. Note that FIG. 53 illustrates the example of the shape of the rising type sawtooth pulse, and the shape is not limited thereto. For example, the shape can also be a shape in which the non-rectangular pulse illustrated in any one of FIGS. 30 to 33 is inverted on the time axis and a starting voltage is set to zero. That is, the shape of the rising type sawtooth pulse is a shape in which the amplitude gradually increases from zero linearly, curvilinearly, or stepwise to a desired amplitude value, and changes from the desired amplitude value to zero.

In the same manner as above, a constraint for the shape of the rising type sawtooth pulse was simulated. The shape of the rising type sawtooth pulse includes a termination voltage V and a rise width t3 illustrated in FIG. 53. The termination voltage V and the rise width t3 were varied by a grid. Note that there are a case where the bit line BL is used and a case where the word line WL is used when a voltage pulse is applied to the memory cell 100. Since the bit line BL is used here, simulation results using the termination voltage V as the bit line voltage V_{BL} are illustrated in FIG. 54. A black strip-shaped portion in FIG. 54 is a region where writing of State 0 is successful regardless of the initial state. It can be understood that the bit line voltage V_{BL} that enables the non-toggle writing exists when the rise width is 2 ns or more. For example, when the fall width is 10 ns, a width of the bit line voltage V_{BL} is about 220 mV. Since the width of the bit line voltage V_{BL} in the case of the rectangular long pulse illustrated in FIG. 42 is 60 mV, it can be understood that an operation margin of 3.7 times is obtained.

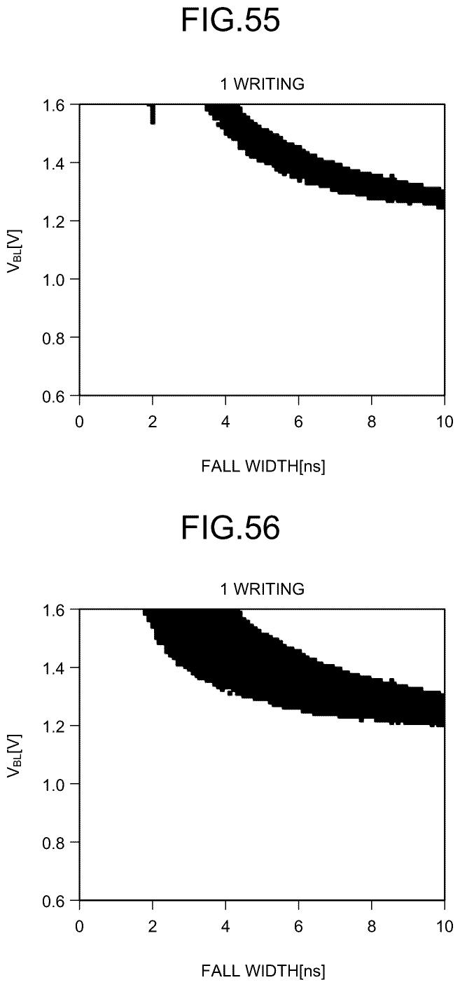

Further, simulation results in the case of writing of State 1 are illustrated in FIGS. 55 and 56. A black strip-shaped portion in FIG. 55 is a region where the writing of State 1 is successful regardless of the initial state, and a black strip-shaped portion in FIG. 56 is a region where the writing of State 1 is successful only when the initial state is State 0. Further, when FIGS. 55 and 56 are compared, the region where the writing is successful is wider when the initial state is limited to “0”. For this reason, when the initial state is State 1, it is possible to use the scheme of writing State 0 before writing State 1, and then writing State 1. This scheme will be described in <1-12> below.

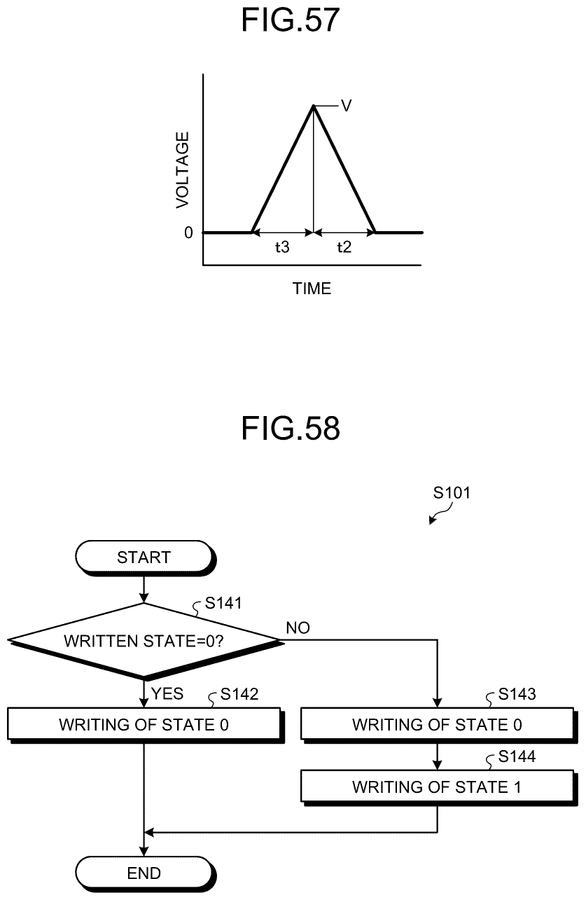

Note that a triangular sawtooth pulse (triangular pulse) as illustrated in FIG. 57 can be used as the sawtooth pulse, in addition to the falling type sawtooth pulse and the rising type sawtooth pulse. Specifically, a shape of the triangular sawtooth pulse is a shape in which the amplitude gradually increases from zero to a desired amplitude value, and gradually decreases from the desired amplitude value to zero as illustrated in FIG. 57. In an example of FIG. 57, the shape of the triangular sawtooth pulse is a shape in which the amplitude gradually increases from zero linearly to a desired amplitude value, and gradually decreases from the desired amplitude value linearly to zero. The shape of the triangular sawtooth pulse is not particularly limited, and may be, for example, a shape in which the amplitude gradually increases from zero curvilinearly or stepwise or gradually decreases from a desired amplitude value curvilinearly or stepwise. Further, the shape of the triangular sawtooth pulse may be set by appropriately changing the rise width t3 and the fall width t2.

### 1-12. Write Scheme Using Initial Writing

A write scheme using initial writing according to the present embodiment will be described with reference to FIGS. 58 to 62.

FIG. 58 is a view illustrating an example of a

processing procedure of write processing of the write scheme using the initial writing according to the present embodiment. This drawing is an example of writing (step S101) performed by the write circuit 70 in the writing processing (step S100) in the memory system 1 illustrated in FIG. 16. First, the memory control unit 3 determines whether a state to be written is State 0 (step S141). As a result, in a case where the state to be written is State 0 (Yes in step S141), the write circuit 70 writes State 0 (step S142), and the processing is ended. On the other hand, in step S141, when the state to be written is State 1 (No in step S141), the write circuit 70 writes State 0 (step S143). Thereafter, the write circuit 70 writes State 1 (step S144), and the processing is ended.

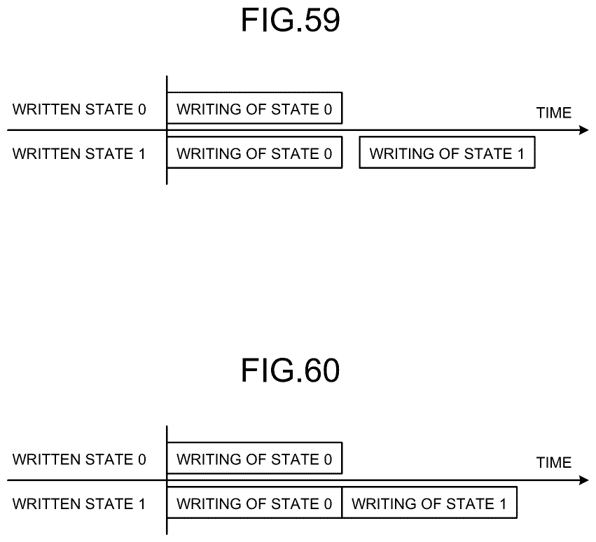

FIGS. 59 and 60 are views for describing the write scheme using the initial writing according to the present embodiment. Each drawing illustrates a variation of a method for applying a pulse voltage in the write scheme using the initial writing illustrated in FIG. 58. In FIG. 59, writing of State 0 and writing of State 1 are independent of each other. On the other hand, in FIG. 60, the writing of State 0 and the writing of State 1 are continuous. That is, a shape of a write pulse is a shape obtained by connecting a pulse shape for writing State 0 and a pulse shape for writing State 1.

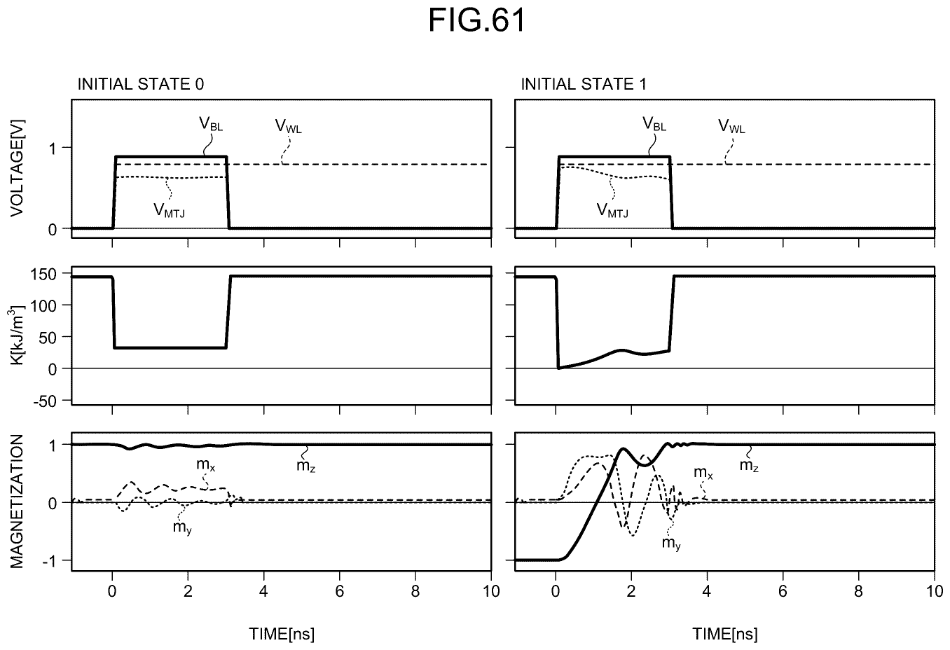

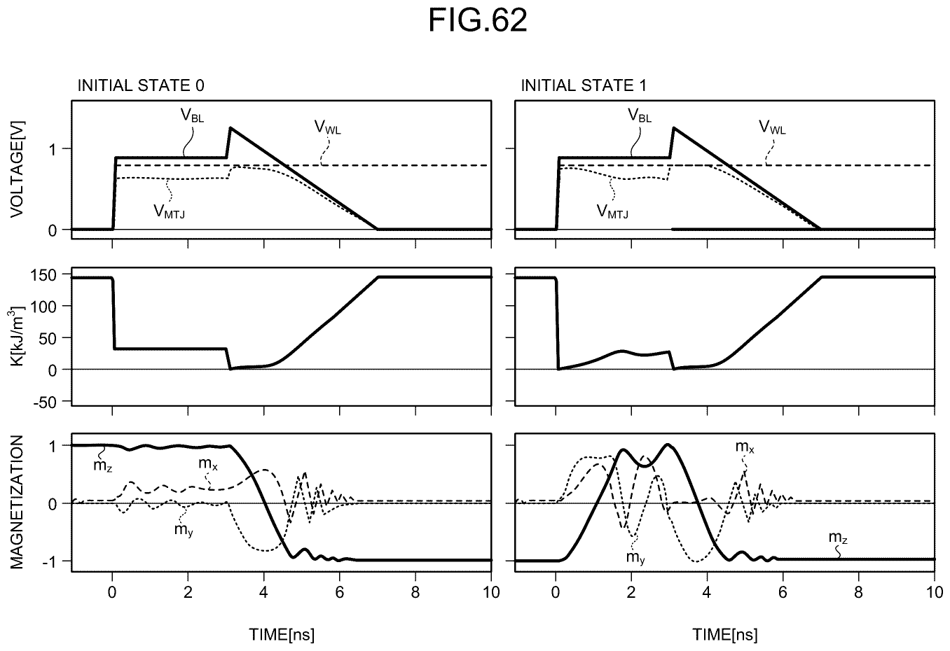

FIGS. 61 and 62 illustrate simulation results of the write scheme using the initial writing according to the present embodiment. The state to be written is State 0 (State 0 is to be written) in FIG. 61, and the state to be written is State 1 (State 1 is to be written) in FIG. 62. In examples of FIGS. 61 and 62, a rectangular long pulse is used for the writing of State 0, and a falling type sawtooth pulse is used for the writing of State 1. Further, in the example of FIG. 62, the writing of State 0 and the writing of State 1 are continuous as illustrated in FIG. 60. FIG. 61 illustrates the independent writing of State 0, and thus, is similar to the results in FIGS. 40 and 41. In FIG. 62, the falling type sawtooth pulse is continuously applied after the writing of State 0 using the rectangular long pulse. That is, a plurality of pulses having different pulse waveforms are continuous. When the initial state is State 0, there is no state change in the case of writing of State 0. Thereafter, State 1 is written by the application of the falling type sawtooth pulse. On the other hand, when the initial state is State 1, State 0 is written in the case of writing of State 0. Thereafter, State 1 is written by the application of the falling type sawtooth pulse. Since the writing of State 1 with respect to State 1 is avoided in this manner, a write margin increases.

Note that the write pulses used in the respective write schemes from the write scheme using the gradient long pulse in <1-10> described above to the write scheme using the initial writing in <1-12> described above can be generated by using each of the write pulse generation circuits 200 and 210 illustrated in <1-8> described above alone or in combination.

### 1-13. Action and Effect

As described above, according to the embodiment, the memory system 1, which functions as the storage device, includes the magnetoresistive element 120 whose magnetization direction is variable between a first state (for example, State 1) and a second state (for example, State 0) by voltage application; the selection element 110 connected to the magnetoresistive element 120; and the write unit (for example, the write circuit 70) that switchably applies, to the magnetoresistive element 120, a first write voltage (for example, the MTJ voltage V_{MTJ}) for setting the magnetization direction of the magnetoresistive element 120 to the first state and a second write voltage (for example, the MTJ voltage V_{MTJ}) for setting the magnetization direction of the magnetoresistive element 120 to the second state. As a result, it is possible to perform non-toggle writing that does not require reading of an initial state before writing. As a result, read time and power consumption required at the time of initial reading can be reduced, and high-speed and low-power consumption writing can be implemented.

Further, the write unit may apply a pulse voltage as one or both of the first write voltage and the second write voltage to the magnetoresistive element 120. As a result, the high-speed and low-power-consumption writing can be reliably implemented.

Further, the write unit may continuously repeat the application of the pulse voltage to the magnetoresistive element 120. As a result, a write error rate can be reduced.

Further, a pulse width or an amplitude of the pulse voltage may be different for each application of the pulse voltage. As a result, the write error rate can be reliably reduced.

Further, the write unit may read a state of the magnetization direction of the magnetoresistive element 120 after the application of the pulse voltage (for example, after continuously repeating the application of the pulse voltage), and apply the pulse voltage again in a case where the read state is not a desired state (for example, continuously repeat the application of the pulse voltage). As a result, the write error rate can be reliably reduced.

Further, the pulse voltage may be a pulse voltage having a pulse width of 0.1 ns or more and 20 ns or less. As a result, the write error rate can be reliably reduced.

Further, a pulse waveform of the pulse voltage used as the first write voltage may be different from a pulse waveform of the pulse voltage used as the second write voltage. As a result, it is possible to improve the stability of writing (for example, to reduce the write error rate).

Further, a pulse waveform of the pulse voltage may have a shape in which the amplitude changes from zero to a first amplitude value and the first amplitude value is maintained until a termination of the pulse waveform. As a result, it is possible to reliably improve the stability of writing.

Further, the pulse waveform of the pulse voltage may have a non-rectangular shape. As a result, it is possible to reliably improve the stability of writing.

Further, the non-rectangular pulse waveform may have a first shape in which the amplitude changes from zero to a first amplitude value, gradually decreases or increases from the first amplitude value to a second amplitude value, and changes from the second amplitude value to zero. As a result, it is possible to reliably improve the stability of writing.

Further, the non-rectangular pulse waveform may have a shape that decreases or increases linearly, curvilinearly, or stepwise from the first amplitude value to the second amplitude value in the first shape described above. As a result, it is possible to reliably improve the stability of writing.

Further, the non-rectangular pulse waveform may have a second shape in which the amplitude changes from zero to a first amplitude value, gradually decreases or increases from the first amplitude value to a second amplitude value, and the second amplitude value is maintained until a termination of the pulse waveform. As a result, it is possible to reliably improve the stability of writing.

Further, the non-rectangular pulse waveform may have a shape that decreases or increases linearly, curvilinearly, or stepwise from the first amplitude value to the second amplitude value in the second shape described above. As a result, it is possible to reliably improve the stability of writing.

Further, the non-rectangular pulse waveform may have a third shape in which the amplitude changes from zero to a first amplitude value and gradually decreases from the first amplitude value to zero. As a result, it is possible to reliably improve the stability of writing.

Further, the non-rectangular pulse waveform may have a shape that decreases linearly, curvilinearly, or stepwise from the first amplitude value to zero in the third shape described above. As a result, it is possible to reliably improve the stability of writing.

Further, the non-rectangular pulse waveform may have a fourth shape in which the amplitude gradually increases from zero to the first amplitude value, and changes from the first amplitude value to zero. As a result, it is possible to reliably improve the stability of writing.

Further, the non-rectangular pulse waveform may have a shape in which the amplitude increases linearly, curvilinearly, or stepwise from zero to the first amplitude value in the fourth shape described above. As a result, it is possible to reliably improve the stability of writing.

Further, the non-rectangular pulse waveform may have a fifth shape in which the amplitude gradually increases from zero to the first amplitude value and gradually decreases from the first amplitude value to zero. As a result, it is possible to reliably improve the stability of writing.

Further, the non-rectangular pulse waveform may have a shape in which the amplitude increases linearly, curvilinearly, or stepwise from zero to the first amplitude value and decreases linearly, curvilinearly, or stepwise from the first amplitude value to zero in the fifth shape described above. As a result, it is possible to reliably improve the stability of writing.

Further, the write unit may apply the first write voltage when the magnetization direction of the magnetoresistive element 120 is set to the first state, and apply the second write voltage after the application of the first write voltage when the magnetization direction of the magnetoresistive element 120 is set to the second state. As a result, a write margin increases, and thus, it is possible to reliably improve the stability of writing.

Further, the selection element 110 may have a drain terminal, a source terminal, and a gate terminal, one terminal of two terminals of the magnetoresistive element 120 may be connected to the bit line 12, the other terminal may be connected to the drain terminal, the source terminal may be connected to the source line 13, and the gate terminal may be connected to the word line 11 (see FIG. 3). With such a first configuration, the high-speed and low-power-consumption writing can also be implemented.

Further, the selection element 110 may have a drain terminal, a source terminal, and a gate terminal, one terminal of two terminals of the magnetoresistive element 120 may be connected to the source line 13, the other terminal may be connected to the source terminal, the drain terminal may be connected to the bit line 12, and the gate terminal may be connected to the word line 11 (see FIG. 4). With such a second configuration, the high-speed and low-power-consumption writing can also be implemented.

Further, in the first configuration or the second configuration described above, the write unit may apply a first voltage (for example, GND) to the source line 13, apply a second voltage (for example, V1 in FIG. 10) to the bit line 12 or the word line 11, apply a first pulse voltage (for example, V2 in FIG. 11) to the word line 11 or the bit line 12 to apply the first write voltage to the magnetoresistive element 120 in a case where the magnetization direction of the magnetoresistive element 120 is set to the first state, and apply a second pulse voltage (for example, V3 in FIG. 11) to the word line 11 or the bit line 12 to apply the second write voltage to the magnetoresistive element 120 in a case where the magnetization direction of the magnetoresistive element 120 is set to the second state. As a result, the high-speed and low-power-consumption writing can be reliably implemented.

Further, the first pulse voltage may be higher than the second pulse voltage. As a result, the high-speed and low-power-consumption writing can be more reliably implemented.

Further, in the first configuration or the second configuration described above, the write unit may apply a third voltage (for example, GND) to the source line 13, apply a third pulse voltage (for example, V6 in FIG. 14) to the word line 11 or the bit line 12, apply a fourth voltage (for example, V4 in FIG. 13) to the bit line 12 or the word line 11 to apply the first write voltage to the magnetoresistive element 120 in a case where the magnetization direction of the magnetoresistive element 120 is set to the first state, and apply a fifth voltage (for example, V5 in FIG. 13) to the bit line 12 or the word line 11 to apply the second write voltage to the magnetoresistive element 120 in a case where the magnetization direction of the magnetoresistive element 120 is set to the second state. As a result, the high-speed and low-power-consumption writing can be reliably implemented.

Further, the fourth voltage may be higher than the fifth voltage. As a result, the high-speed and low-power-consumption writing can be more reliably implemented.

### 2. Other Embodiments

The configurations according to the above embodiment may be implemented in various different forms other than the above embodiment. For example, the configurations are not limited to the above-described examples, and may have various modes. Further, for example, the configurations, processing procedures, specific names, and information including various types of data and parameters illustrated in the above document and drawings can be arbitrarily changed unless otherwise specified.

Further, each component of each device illustrated is a functional concept, and does not necessarily need to be physically configured as illustrated. That is, the specific form of distribution/integration of each device is not limited to those illustrated in the drawings, and all or a part thereof may be functionally or physically distributed/integrated into arbitrary units according to various loads and usage situations.

For example, the MTJ according to each of the above embodiment and modifications thereof may be used as the magnetoresistive element 120, and a storage device such as a hard disk drive (HDD) may be configured as the storage device.

### 3. Configuration Example of Electronic Apparatus

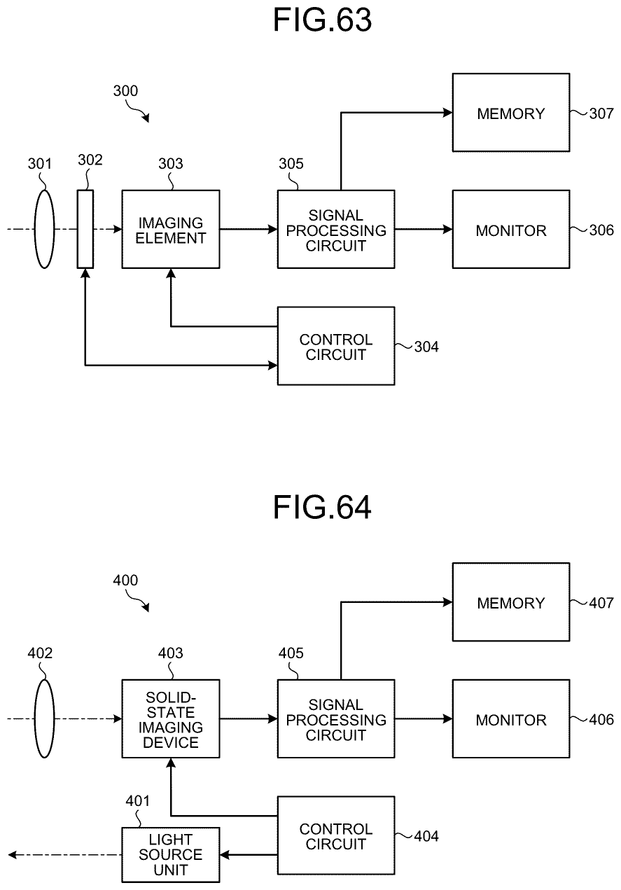

As an electronic apparatus to which the memory system 1 according to the above embodiment (including modifications) is applied, an imaging device 300, a distance measurement device 400, and a game apparatus 900 will be described with reference to FIGS. 63 to 66. For example, each of the imaging device 300, the distance measurement device 400, and the game apparatus 900 uses the memory system 1 according to each of the above embodiments as a memory. Examples of the memory include a flash memory and the like.

### 3-1. Imaging Device

The imaging device 300 to which the memory system 1 according to the above embodiment is applied will be described with reference to FIG. 63. FIG. 63 is a diagram illustrating an example of a schematic configuration of the imaging device 300. The imaging device 300 is an example of the electronic apparatus to which the memory system 1 according to the present embodiment is applied. Examples of the imaging device 300 include electronic devices such as a digital still camera, a video camera, a smartphone having an imaging function, and a mobile phone.

As illustrated in FIG. 63, the imaging device 300 includes an optical system 301, a shutter device 302, an imaging element 303, a control circuit (drive circuit) 304, a signal processing circuit 305, a monitor 306, and a memory 307. The imaging device 300 can capture a still image and a moving image.

The optical system 301 includes one or a plurality of lenses. The optical system 301 guides light (incident light) from a subject to the imaging element 303 and forms an image on a light receiving surface of the imaging element 303.

The shutter device 302 is disposed between the optical system 301 and the imaging element 303. The shutter device 302 controls a light irradiation period and a light shielding period with respect to the imaging element 303 according to the control of the control circuit 304.

The imaging element 303 accumulates signal charges for a certain period according to light formed on the light receiving surface via the optical system 301 and the shutter device 302. The signal charges accumulated in the imaging element 303 is transferred in accordance with a drive signal (timing signal) supplied from the control circuit 304.

The control circuit 304 outputs the drive signal for controlling a transfer operation of the imaging element 303 and a shutter operation of the shutter device 302 to drive the imaging element 303 and the shutter device 302.

The signal processing circuit 305 performs various types of signal processing on the signal charges output from the imaging element 303. An image (image data) obtained by performing the signal processing by the signal processing circuit 305 is supplied to the monitor 306 and also supplied to the memory 307.

The monitor 306 displays a moving image or a still image captured by the imaging element 303 based on the image data supplied from the signal processing circuit 305. As the monitor 306, for example, a panel type display device such as a liquid crystal panel or an organic electro luminescence (EL) panel is used.

The memory 307 stores the image data supplied from the signal processing circuit 305, that is, image data of the moving image or the still image captured by the imaging element 303. The memory 307 corresponds to the memory device 1 according to the above embodiment.

Also in the imaging device 300 configured in this manner, high-speed and low-power-consumption writing can be implemented by using the above-described memory system 1 as the memory 307.

### 3-2. Distance Measurement Device

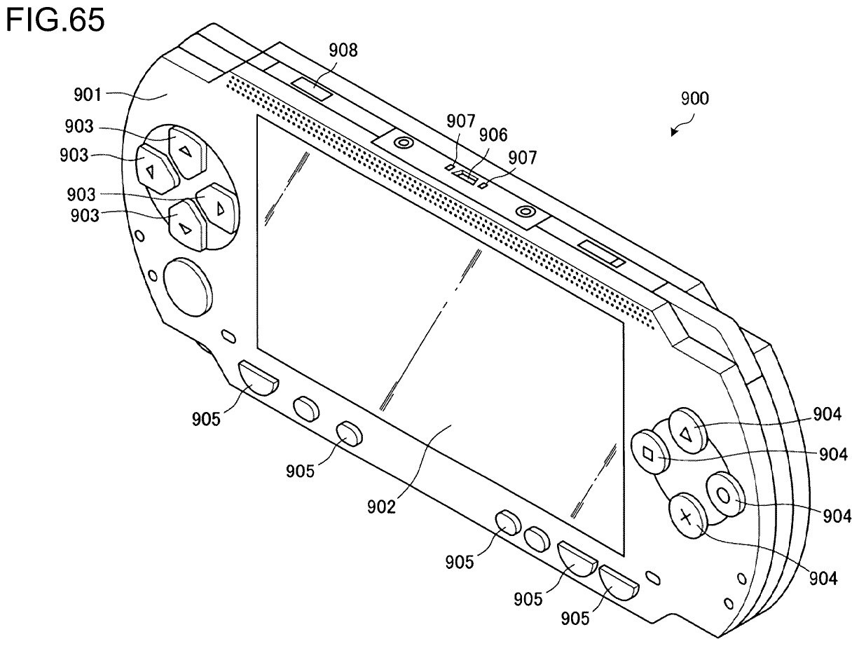

The distance measurement device 400 to which the memory system 1 according to the above embodiment is applied will be described with reference to FIG. 64. FIG. 64 is a diagram illustrating an example of a schematic configuration of the distance measurement device 400. The distance measurement device 400 is an example of the electronic apparatus to which the memory system 1 according to the present embodiment is applied.

As illustrated in FIG. 64, the distance measurement device (distance image sensor) 400 includes a light source unit 401, an optical system 402, a solid-state imaging device (imaging element) 403, a control circuit (drive circuit) 404, a signal processing circuit 405, a monitor 406, and a memory 407. The distance measurement device 400 can acquire a distance image according to a distance to a subject by projecting light from the light source unit 401 toward the subject and receiving light (modulated light or pulsed light) reflected from a surface of the subject.

The light source unit 401 projects light toward the subject. As the light source unit 401, for example, a vertical cavity surface emitting laser (VCSEL) array that emits laser light as a surface light source or a laser diode array in which laser diodes are arrayed on a line is used. Note that the laser diode array is supported by a predetermined drive unit (not illustrated), and is scanned in a direction perpendicular to the array direction of the laser diodes.

The optical system 402 includes one or a plurality of lenses. The optical system 402 guides light (incident light) from the subject to the solid-state imaging device 403 to form an image on a light receiving surface (sensor unit) of the solid-state imaging device 403.

The solid-state imaging device 403 stores signal charges according to the light of the image formed on the light receiving surface via the optical system 402. A distance signal indicating the distance obtained from a light reception signal (APD OUT) output from the solid-state imaging device 403 is supplied to the signal processing circuit 405. As the solid-state imaging device 403, for example, a solid-state imaging element such as an image sensor is used.

The control circuit 404 outputs a drive signal (control signal) for controlling operations of the light source unit 401, the solid-state imaging device 403, and the like to drive the light source unit 401, the solid-state imaging device 403, and the like.

The signal processing circuit 405 performs various types of signal processing on the distance signal supplied from the solid-state imaging device 403. For example, the signal processing circuit 405 performs image processing (for example, histogram processing, peak detection processing, and the like) of constructing the distance image on the basis of the distance signal. An image (image data) obtained by performing the signal processing by the signal processing circuit 405 is supplied to the monitor 406 and also supplied to the memory 407.

The monitor 406 displays the distance image captured by the imaging element 303 on the basis of the image data supplied from the signal processing circuit 405. As the monitor 406, for example, a panel type display device such as a liquid crystal panel or an organic EL panel is used.

The memory 407 stores the image data supplied from the signal processing circuit 405, that is, the image data of the distance image captured by the imaging element 303. The memory 407 corresponds to the memory system 1 according to the above embodiment.

Also in the distance measurement device 400 configured in this manner, high-speed and low-power-consumption writing can be implemented by using the above-described memory system 1 as the memory 407.

### 3-3. Game Device

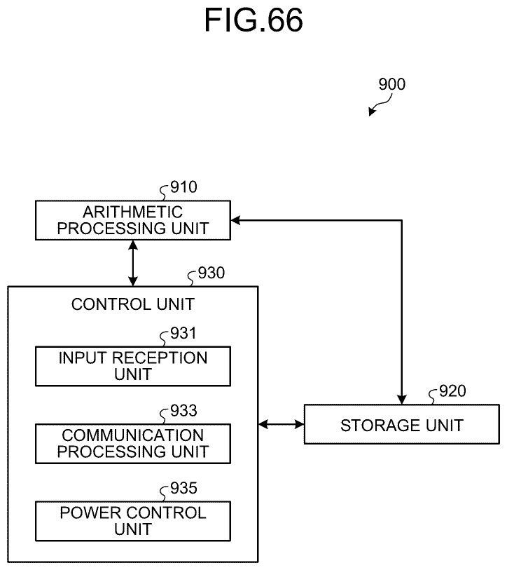

The game device 900 to which the memory system 1 according to the above embodiment is applied will be described with reference to FIGS. 65 and 66. FIG. 65 is a perspective view (external perspective view) illustrating an example of the schematic configuration of the game device 900. FIG. 66 is a block diagram illustrating an example of the schematic configuration of the game device 900. The game device 900 is an example of the electronic apparatus to which the memory system 1 according to the present embodiment is applied.

As illustrated in FIG. 65, for example, the game device 900 has an appearance in which each component is disposed inside and outside an outer casing 901 formed in a horizontally long flat shape.

On the front surface of the outer casing 901, a display panel 902 is provided at the center thereof in the longitudinal direction. Further, operation keys 903 and operation keys 904 are provided on the left and right sides of the display panel 902, respectively, spaced apart from each other in the circumferential direction. An operation key 905 is provided at a lower end of the front surface of the outer casing 901. The operation keys 903, 904, and 905 function as direction keys, determination keys, or the like, and are used for selection of menu items displayed on the display panel 902, progress of a game, or the like.

On the upper surface of the outer casing 901, a connection terminal 906 for connecting an external device, a power supply terminal 907, a light receiving window 908 for performing infrared communication with the external device, and the like are provided.

As illustrated in FIG. 66, the game device 900 includes an arithmetic processing unit 910 including a central processing unit (CPU), a storage unit 920 that stores various types of information, and a controller 930 that controls each configuration of the game device 900. Power is supplied to the arithmetic processing unit 910 and the controller 930 from, for example, a battery (not illustrated) or the like.

The arithmetic processing unit 910 generates a menu screen for allowing a user to set various types of information or select an application. In addition, the arithmetic processing unit 910 executes the application selected by the user.

The storage unit 920 stores various types of information set by the user. The storage unit 920 corresponds to the memory system 1 according to the above embodiment.

The controller 930 includes an input receiving unit 931, a communication processing unit 933, and a power controller 935. The input receiving unit 931 detects, for example, the states of the operation keys 903, 904, and 905. Furthermore, the communication processing unit 933 performs communication processing with an external device. The power controller 935 controls power supplied to each unit of the game device 900.

Also in the game device 900 configured in this manner, high-speed and low-power-consumption writing can be implemented by using the above-described memory system 1 as the storage unit 920.

It is noted that the memory system 1 according to each of the above-described embodiments may be mounted on the same semiconductor chip together with a semiconductor circuit forming an arithmetic device or the like to form a semiconductor device (System-on-a-Chip: SoC).

Furthermore, the memory system 1 according to the above embodiment can be mounted on various electronic devices on which a memory (storage unit) can be mounted as described above. For example, the memory system 1 may be mounted on various electronic devices such as a notebook personal computer (PC), a mobile device (for example, a smartphone, a tablet PC, or the like), a personal digital assistant (PDA), a wearable device, and a music device in addition to the imaging device 300 and the game device 900. For example, the memory system 1 is used as various memories such as a storage.

### 4. Appendix

Note that the present technology can also have the following configurations.
(1)

A storage device comprising:
a magnetoresistive element whose magnetization direction is variable between a first state and a second state by voltage application;
a selection element connected to the magnetoresistive element; and
a write unit that switchably applies, to the magnetoresistive element, a first write voltage for setting the magnetization direction of the magnetoresistive element to the first state and a second write voltage for setting the magnetization direction of the magnetoresistive element to the second state.
(2)

The storage device according to (1), wherein
the write unit applies a pulse voltage as one or both of the first write voltage and the second write voltage to the magnetoresistive element.
(3)

The storage device according to (2), wherein
the write unit continuously repeats the application of the pulse voltage to the magnetoresistive element.
(4)

The storage device according to (3), wherein
a pulse width or an amplitude of the pulse voltage is different for each application of the pulse voltage.
(5)

The storage device according to any one of (2) to (4), wherein
the write unit reads a state of the magnetization direction of the magnetoresistive element after the application of the pulse voltage, and applies the pulse voltage again when the read state is not a desired state.
(6)

The storage device according to any one of (2) to (5), wherein
the pulse voltage is a pulse voltage having a pulse width of 0.1 ns or more and 20 ns or less.
(7)

The storage device according to any one of (2) to (6), wherein
a pulse waveform of the pulse voltage used as the first write voltage is different from a pulse waveform of the pulse voltage used as the second write voltage.
(8)

The storage device according to any one of (2) to (7), wherein
a pulse waveform of the pulse voltage has a shape in which an amplitude changes from zero to a first amplitude value and the first amplitude value is maintained until a termination of the pulse waveform.
(9)

The storage device according to any one of (2) to (7), wherein
a pulse waveform of the pulse voltage has a non-rectangular shape.
(10)

The storage device according to (9), wherein
the pulse waveform of the pulse voltage has a shape in which an amplitude changes from zero to a first amplitude value, gradually decreases or increases from the first amplitude value to a second amplitude value, and changes from the second amplitude value to zero.
(11)

The storage device according to (10), wherein
the pulse waveform of the pulse voltage has a shape that decreases or increases linearly, curvilinearly, or stepwise from the first amplitude value to the second amplitude value.
(12)

The storage device according to (9), wherein
the pulse waveform of the pulse voltage has a shape in which an amplitude changes from zero to a first amplitude value, gradually decreases or increases from the first amplitude value to a second amplitude value, and the second amplitude value is maintained until a termination of the pulse waveform.
(13)

The storage device according to (12), wherein
the pulse waveform of the pulse voltage has a shape that decreases or increases linearly, curvilinearly, or stepwise from the first amplitude value to the second amplitude value.
(14)

The storage device according to (9), wherein
the pulse waveform of the pulse voltage has a shape in which an amplitude changes from zero to a first amplitude value and gradually decreases from the first amplitude value to zero.
(15)

The storage device according to (14), wherein
the pulse waveform of the pulse voltage has a shape that decreases linearly, curvilinearly, or stepwise from the first amplitude value to zero.
(16)

The storage device according to (9), wherein
the pulse waveform of the pulse voltage has a shape in which an amplitude gradually increases from zero to a first amplitude value and changes from the first amplitude value to zero.
(17)

The storage device according to (16), wherein
the pulse waveform of the pulse voltage has a shape in which the amplitude increases linearly, curvilinearly, or stepwise from zero to the first amplitude value.
(18)

The storage device according to (9), wherein
the pulse waveform of the pulse voltage has a shape in which an amplitude gradually increases from zero to a first amplitude value and gradually decreases from the first amplitude value to zero.
(19)

The storage device according to (18), wherein
the pulse waveform of the pulse voltage has a shape in which the amplitude increases linearly, curvilinearly, or stepwise from zero to the first amplitude value, and decreases linearly, curvilinearly, or stepwise from the first amplitude value to zero.
(20)

The storage device according to any one of (1) to (19), wherein
the write unit
applies the first write voltage when the magnetization direction of the magnetoresistive element is set to the first state, and
applies the first write voltage, and then applies the second write voltage when the magnetization direction of the magnetoresistive element is set to the second state.
(21)

The storage device according to any one of (1) to (20), wherein
the selection element has a drain terminal, a source terminal, and a gate terminal,
one terminal of two terminals of the magnetoresistive element is connected to a bit line, and another terminal is connected to the drain terminal,
the source terminal is connected to a source line, and
the gate terminal is connected to a word line.
(22)

The storage device according to any one of (1) to (20), wherein
the selection element has a drain terminal, a source terminal, and a gate terminal,
one terminal of two terminals of the magnetoresistive element is connected to a source line, and another terminal is connected to the source terminal,
the drain terminal is connected to a bit line, and
the gate terminal is connected to a word line.
(23)

The storage device according to (21), wherein
the write unit applies a first voltage to the source line, applies a second voltage to the bit line or the word line, applies a first pulse voltage to the word line or the bit line to apply the first write voltage to the magnetoresistive element in a case where the magnetization direction of the magnetoresistive element is set to the first state, and applies a second pulse voltage to the word line or the bit line to apply the second write voltage to the magnetoresistive element in a case where the magnetization direction of the magnetoresistive element is set to the second state.
(24)

The storage device according to (22), wherein
the write unit applies a first voltage to the source line, applies a second voltage to the bit line or the word line, applies a first pulse voltage to the word line or the bit line to apply the first write voltage to the magnetoresistive element in a case where the magnetization direction of the magnetoresistive element is set to the first state, and applies a second pulse voltage to the word line or the bit line to apply the second write voltage to the magnetoresistive element in a case where the magnetization direction of the magnetoresistive element is set to the second state.
(25)

The storage device according to (23) or (24), wherein
the first pulse voltage is higher than the second pulse voltage.
(26)

The storage device according to (21), wherein
the write unit applies a third voltage to the source line, applies a third pulse voltage to the word line or the bit line, applies a fourth voltage to the bit line or the word line to apply the first write voltage to the magnetoresistive element in a case where the magnetization direction of the magnetoresistive element is set to the first state, and applies a fifth voltage to the bit line or the word line to apply the second write voltage to the magnetoresistive element in a case where the magnetization direction of the magnetoresistive element is set to the second state.
(27)

The storage device according to (22), wherein
the write unit applies a third voltage to the source line, applies a third pulse voltage to the word line or the bit line, applies a fourth voltage to the bit line or the word line to apply the first write voltage to the magnetoresistive element in a case where the magnetization direction of the magnetoresistive element is set to the first state, and applies a fifth voltage to the bit line or the word line to apply the second write voltage to the magnetoresistive element in a case where the magnetization direction of the magnetoresistive element is set to the second state.
(28)

The storage device according to (26) or (27), wherein
the fourth voltage is higher than the fifth voltage.
(29)

An electronic apparatus comprising
a storage device that stores data,
the storage device including:
a magnetoresistive element whose magnetization direction is variable between a first state and a second state by voltage application;
a selection element connected to the magnetoresistive element; and
a write unit that switchably applies, to the magnetoresistive element, a first write voltage for setting the magnetization direction of the magnetoresistive element to the first state and a second write voltage for setting the magnetization direction of the magnetoresistive element to the second state.
(30)

A storage device control method comprising
switchably applying, to a magnetoresistive element whose magnetization direction is variable between a first state and a second state by voltage application, a first write voltage for setting the magnetization direction of the magnetoresistive element to the first state and a second write voltage for setting the magnetization direction of the magnetoresistive element to the second state.
(31)

An electronic apparatus including the storage device according to any one of (1) to (28).
(32)

A storage device control method for controlling the storage device according to any one of (1) to (28).

### REFERENCE SIGNS LIST

1 MEMORY SYSTEM
2 INTERFACE UNIT
3 MEMORY CONTROL UNIT
4 MEMORY ARRAY
10 MEMORY CELL ARRAY
11 WORD LINE
12 BIT LINE
13 SOURCE LINE
20 WORD LINE ADDRESS DECODER
30 WORD LINE CONTROL CIRCUIT
40 BIT LINE ADDRESS DECODER
50 BIT LINE CONTROL CIRCUIT
60 SENSE AMPLIFIER
70 WRITE CIRCUIT
80 READ CIRCUIT
90 VOLTAGE GENERATION CIRCUIT
100 MEMORY CELL
101 WIRING
102 WIRING
103 CONTACT LAYER
104 CONTACT LAYER
110 SELECTION ELEMENT
120 MAGNETORESISTIVE ELEMENT
121 BASE LAYER
122 MAGNETIZATION FIXED LAYER
123 TUNNEL BARRIER LAYER
124 STORAGE LAYER
125 CAP LAYER
200 WRITE PULSE GENERATION CIRCUIT
201 INPUT END
202 CR CIRCUIT
203 TRANSFER GATE
204 OPERATIONAL AMPLIFIER
205 OUTPUT TERMINAL
206 OUTPUT
207 NON-INVERTING INPUT
210 WRITE PULSE GENERATION CIRCUIT
211 WAVEFORM MEMORY
212 D/A CONVERSION CIRCUIT
300 IMAGING DEVICE
307 MEMORY
400 DISTANCE MEASUREMENT DEVICE
407 MEMORY
900 GAME APPARATUS
920 STORAGE UNIT

1. A storage device comprising:
a magnetoresistive element whose magnetization direction is variable between a first state and a second state by voltage application;
a selection element connected to the magnetoresistive element; and
a write unit that switchably applies, to the magnetoresistive element, a first write voltage for setting the magnetization direction of the magnetoresistive element to the first state and a second write voltage for setting the magnetization direction of the magnetoresistive element to the second state.

2. The storage device according to claim 1, wherein
the write unit applies a pulse voltage as one or both of the first write voltage and the second write voltage to the magnetoresistive element.

3. The storage device according to claim 2, wherein
the write unit continuously repeats the application of the pulse voltage to the magnetoresistive element.

4. The storage device according to claim 3, wherein
a pulse width or an amplitude of the pulse voltage is different for each application of the pulse voltage.

5. The storage device according to claim 2, wherein
the write unit reads a state of the magnetization direction of the magnetoresistive element after the application of the pulse voltage, and applies the pulse voltage again when the read state is not a desired state.

6. The storage device according to claim 2, wherein
the pulse voltage is a pulse voltage having a pulse width of 0.1 ns or more and 20 ns or less.

7. The storage device according to claim 2, wherein
a pulse waveform of the pulse voltage used as the first write voltage is different from a pulse waveform of the pulse voltage used as the second write voltage.

8. The storage device according to claim 2, wherein
a pulse waveform of the pulse voltage has a shape in which an amplitude changes from zero to a first amplitude value and the first amplitude value is maintained until a termination of the pulse waveform.

9. The storage device according to claim 2, wherein
a pulse waveform of the pulse voltage has a non-rectangular shape.

10. The storage device according to claim 9, wherein
the pulse waveform of the pulse voltage has a shape in which an amplitude changes from zero to a first amplitude value, gradually decreases or increases from the first amplitude value to a second amplitude value, and changes from the second amplitude value to zero.

11. The storage device according to claim 10, wherein
the pulse waveform of the pulse voltage has a shape that decreases or increases linearly, curvilinearly, or stepwise from the first amplitude value to the second amplitude value.

12. The storage device according to claim 9, wherein
the pulse waveform of the pulse voltage has a shape in which an amplitude changes from zero to a first amplitude value, gradually decreases or increases from the first amplitude value to a second amplitude value, and the second amplitude value is maintained until a termination of the pulse waveform.

13. The storage device according to claim 12, wherein
the pulse waveform of the pulse voltage has a shape that decreases or increases linearly, curvilinearly, or stepwise from the first amplitude value to the second amplitude value.

14. The storage device according to claim 9, wherein
the pulse waveform of the pulse voltage has a shape in which an amplitude changes from zero to a first amplitude value and gradually decreases from the first amplitude value to zero.

15. The storage device according to claim 14, wherein
the pulse waveform of the pulse voltage has a shape that decreases linearly, curvilinearly, or stepwise from the first amplitude value to zero.

16. The storage device according to claim 9, wherein
the pulse waveform of the pulse voltage has a shape in which an amplitude gradually increases from zero to a first amplitude value and changes from the first amplitude value to zero.

17. The storage device according to claim 16, wherein
the pulse waveform of the pulse voltage has a shape in which the amplitude increases linearly, curvilinearly, or stepwise from zero to the first amplitude value.

18. The storage device according to claim 9, wherein
the pulse waveform of the pulse voltage has a shape in which an amplitude gradually increases from zero to a first amplitude value and gradually decreases from the first amplitude value to zero.

19. The storage device according to claim 18, wherein
the pulse waveform of the pulse voltage has a shape in which the amplitude increases linearly, curvilinearly, or stepwise from zero to the first amplitude value, and decreases linearly, curvilinearly, or stepwise from the first amplitude value to zero.

20. The storage device according to claim 1, wherein
the write unit
applies the first write voltage when the magnetization direction of the magnetoresistive element is set to the first state, and
applies the first write voltage, and then applies the second write voltage when the magnetization direction of the magnetoresistive element is set to the second state.

21. The storage device according to claim 1, wherein
the selection element has a drain terminal, a source terminal, and a gate terminal,
one terminal of two terminals of the magnetoresistive element is connected to a bit line, and another terminal is connected to the drain terminal,
the source terminal is connected to a source line, and
the gate terminal is connected to a word line.

22. The storage device according to claim 1, wherein
the selection element has a drain terminal, a source terminal, and a gate terminal,
one terminal of two terminals of the magnetoresistive element is connected to a source line, and another terminal is connected to the source terminal,
the drain terminal is connected to a bit line, and
the gate terminal is connected to a word line.

23. The storage device according to claim 21, wherein
the write unit applies a first voltage to the source line, applies a second voltage to the bit line or the word line, applies a first pulse voltage to the word line or the bit line to apply the first write voltage to the magnetoresistive element in a case where the magnetization direction of the magnetoresistive element is set to the first state, and applies a second pulse voltage to the word line or the bit line to apply the second write voltage to the magnetoresistive element in a case where the magnetization direction of the magnetoresistive element is set to the second state.

24. The storage device according to claim 22, wherein
the write unit applies a first voltage to the source line, applies a second voltage to the bit line or the word line, applies a first pulse voltage to the word line or the bit line to apply the first write voltage to the magnetoresistive element in a case where the magnetization direction of the magnetoresistive element is set to the first state, and applies a second pulse voltage to the word line or the bit line to apply the second write voltage to the magnetoresistive element in a case where the magnetization direction of the magnetoresistive element is set to the second state.

25. The storage device according to claim 23, wherein
the first pulse voltage is higher than the second pulse voltage.

26. The storage device according to claim 21, wherein
the write unit applies a third voltage to the source line, applies a third pulse voltage to the word line or the bit line, applies a fourth voltage to the bit line or the word line to apply the first write voltage to the magnetoresistive element in a case where the magnetization direction of the magnetoresistive element is set to the first state, and applies a fifth voltage to the bit line or the word line to apply the second write voltage to the magnetoresistive element in a case where the magnetization direction of the magnetoresistive element is set to the second state.

27. The storage device according to claim 22, wherein
the write unit applies a third voltage to the source line, applies a third pulse voltage to the word line or the bit line, applies a fourth voltage to the bit line or the word line to apply the first write voltage to the magnetoresistive element in a case where the magnetization direction of the magnetoresistive element is set to the first state, and applies a fifth voltage to the bit line or the word line to apply the second write voltage to the magnetoresistive element in a case where the magnetization direction of the magnetoresistive element is set to the second state.

28. The storage device according to claim 26, wherein
the fourth voltage is higher than the fifth voltage.

29. An electronic apparatus comprising
a storage device that stores data,
the storage device including:
a magnetoresistive element whose magnetization direction is variable between a first state and a second state by voltage application;
a selection element connected to the magnetoresistive element; and
a write unit that switchably applies, to the magnetoresistive element, a first write voltage for setting the magnetization direction of the magnetoresistive element to the first state and a second write voltage for setting the magnetization direction of the magnetoresistive element to the second state.

30. A storage device control method comprising
switchably applying, to a magnetoresistive element whose magnetization direction is variable between a first state and a second state by voltage application, a first write voltage for setting the magnetization direction of the magnetoresistive element to the first state and a second write voltage for setting the magnetization direction of the magnetoresistive element to the second state.
